(19) United States
(12) Patent Application Publication
(10) Pub. No.: US 2026/0123052 A1
(43) Pub. Date: Apr. 30, 2026

(54) DRIVER CIRCUITS WITH DIODE STRUCTURES, HAVING HIGH SUBTHRESHOLD SWING AND THRESHOLD VOLTAGE MODULATION AND METHODS OF FORMING THE SAME

(71) Applicant: Taiwan Semiconductor Manufacturing Company Limited, Hsinchu (TW)

(72) Inventors: Jin-Yu LIN, Taichung City (TW); Shiang-Yu CHEN, Hsinchu (TW); Wei-Jen CHANG, Miaoli County (TW); Chia-Chi HO, Zhudong Township (TW); Chung-Shih CHIANG, Zhubei City (TW)

(21) Appl. No.: 18/932,703

(22) Filed: Oct. 31, 2024

(51) Int. Cl. H01L 27/12; G09G 3/20; G09G 3/3233; H01L 25/16

(52) U.S. Cl. CPC H10D 86/60; G09G 3/3233; H10D 86/0221; H10D 86/421; H10W 90/00; G09G 3/2007; G09G 2300/0809; G09G 2320/0233

(57) ABSTRACT

Various embodiments disclosed presents pixel driver circuits that utilize integrated diode structures to enhance sub-threshold swing and modulate threshold voltage. Conventional transistor-only designs often encounter challenges in achieving precise control and efficiency, limited by their sub-threshold swing and voltage modulation capabilities. Various embodiments incorporate advanced MOSFETs in series with diodes without an additional mask and process knob, enabling advanced control over the LED current without a larger area penalty and less process variation with device sub-threshold engineering. Such transistor-diode configuration improves brightness, gray-scale accuracy, and overall display performance, leading to improved power efficiency, advanced display uniformity, and improved reliability for LED devices.

### BACKGROUND

In the field of light-emitting diode pixel driver circuits, pixel driver devices play a central role in improving brightness and gray-scale control. Related pixel driver devices typically include either a p-channel metal-oxide-semiconductor (PMOS) or an n-channel metal-oxide-semiconductor (NMOS) transistor for control, where one transistor determines the switch, and the other transistor controls the brightness. The brightness of the light-emitting diode (LED) is positively correlated with the device current through the controlling transistor.

One of the primary challenges in pixel driver circuits, and in particular Organic light-emitting diodes (OLED), is achieving a high sub-threshold swing (S.S.) necessary for precise brightness control. The sub-threshold swing is defined as the change in gate voltage required to increase the drain current by one order of magnitude in the sub-threshold region. A sub-threshold swing ranges from 80 to 100 mV/dec for typical logic transistors. However, achieving fine gray-scale control in OLED displays needs a higher sub-threshold swing, typically around 200 mV/dec. This higher sub-threshold swing ensures that small changes in gate voltage result in precise control over the current flowing through the OLED, enabling finer adjustments in pixel brightness. In instances in which the sub-threshold swing is too low, even a small variation in gate voltage may lead to large changes in current, making it difficult to achieve smooth gray-scale transitions. Conversely, a higher sub-threshold swing allows for more granular control over the current, facilitating smoother transitions between different brightness levels. This is particularly desired in high-resolution displays, where each pixel's brightness may be meticulously controlled to produce sharp images and accurate colors. The advancements in device structures and configurations discussed here provide the enhancement to meet the stringent requirements of modern LED displays.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a vertical cross-sectional view across cut line AA′ in FIG. 1B of the typical pixel driver n-type field-effect transistor (NFET) transistor with an N+ gate, N+ source/drain, silicide contact, shallow trench isolation (STI) structure, and an associated P-well region.

FIG. 1B shows a top-down view of the transistor, illustrating the placement of the STI, N+ gate, Silicide contact, and an associated P-well.

FIG. 1C presents a schematic diagram of a pixel driver circuit, where T1 is the switch transistor, and T2 controls the pixel brightness. The diagram shows the connection for the data input, scan line, and power Vdd (PVDD), illustrating the operation between NFET transistors and the LED pixel.

FIG. 2A illustrates a vertical cross-sectional view across cut line AA′ in FIG. 2B of the typical pixel driver p-type field-effect transistor (PFET) transistor with a P+ gate, P+ source/drain, silicide contact, shallow trench isolation (STI) structure, and an associated N-well region.

FIG. 2B shows a top-down view of the transistor, illustrating the placement of the STI, P+ gate, Silicide contact, and an associated N-well.

FIG. 2C presents a schematic diagram of a pixel driver circuit, where T1 is the switch transistor, and T2 controls the pixel brightness. The diagram shows the connection for the data input, scan line, and PVDD, illustrating the operation between PFET transistors and the LED pixel.

FIG. 3A-3L are a series of schematic vertical cross-sectional views depicting the sequence of representative process steps to form P-well, STI, Gate oxide, N+ Gate electrode, N+ Source/Drain, diode, and silicide, utilizing photolithographic patterning, ion implantation, and silicide separation by Resist Protective Oxide (RPO).)

FIG. 4A-4M are a series of schematic vertical cross-sectional views and top plan views depicting the sequence of representative process steps to form an alternative embodiment P-well,, Gate oxide, N+ Gate electrode, N+ Source/Drain, mixed cross-coupled diode, and silicide, utilizing photolithographic patterning, ion implantation, and silicide separation by RPO.

FIG. 5A-5G are a series of schematic vertical cross-sectional views depicting the sequence of representative process steps to form an alternative embodiment P-well, STI, Gate oxide, N+ Gate electrode, N+ Source/Drain, diode, and silicide, utilizing photolithographic patterning, ion implantation, and silicide separation by RPO and STI.

FIG. 6A-6G are a series of schematic vertical cross-sectional views depicting the sequence of representative process steps to form an alternative embodiment P-well, Gate oxide, N+ Gate electrode, N+ Source/Drain, diode, and silicide, utilizing photolithographic patterning, ion implantation, and silicide separation by RPO and a dummy gate.

FIG. 6H-6N are a series of schematic vertical cross-sectional views depicting an alternative sequence of representative process steps to form an alternative embodiment P-well, Gate oxide, N+ Gate electrode, N+ Source/Drain, diode, and silicide, utilizing photolithographic patterning, ion implantation, and silicide separation by RPO and a dummy gate.

FIG. 7A-7H are a series of schematic vertical cross-sectional and top plan views depicting the sequence of representative process steps to form an alternative embodiment P-well, Gate oxide, N+ Gate electrode, N+ Source/Drain, mixed cross-coupled diode, and silicide, utilizing photolithographic patterning, ion implantation, and silicide separation by RPO and a dummy gate.

FIG. 8A illustrates a vertical cross-sectional view across cut line AA′ in FIG. 8B of a pixel driver NFET transistor with N+ gate, N+ source/drain, shared silicide contact diode, shallow trench isolation (STI) structure, and an associated P-well region.

FIG. 8B shows a top-down view of the transistor, illustrating the placement of STI, N+ gate, shared silicide contact, and an associated P-well.

FIG. 8C presents a schematic diagram of an LED pixel driver circuit, where T1 is the switch transistor and T2, with a diode, controls the LED brightness. The diagram shows the connection for a data input, a scan line, and PVDD, illustrating an operation between the NFET transistor with a diode and the LED.

FIG. 8D illustrates the energy band diagram corresponding to the cross-section across cut line BB′ in FIG. 8A of a pixel driver NFET transistor with a diode, explaining the operation principle of a T2 transistor with a diode.

FIG. 9A illustrates a vertical cross-sectional view across cut line AA′ in FIG. 9B of a pixel driver PFET transistor with P+ gate, P+ source/drain, shared silicide contact diode, shallow trench isolation (STI) structure, and an associated N-well region.

FIG. 9B shows a top-down view of the transistor, illustrating the placement of STI, P+ gate, shared silicide contact, and an associated N-well.

FIG. 9C presents a schematic diagram of an LED pixel driver circuit, where T1 is the switch transistor and T2, with a diode, controls the LED brightness. The diagram shows the connection for a data input, a scan line, and PVDD, illustrating an operation between the PFET transistor with a diode and the LED.

FIG. 9D illustrates the energy band diagram across cutline BB′ of the PFET transistor-diode device when it is at equilibrium where no external bias is applied to the device, and the Fermi level (Ef) across the different regions is aligned.

FIG. 10A illustrates a vertical cross-sectional view across cut line AA′ in FIG. 10B of a pixel driver NFET transistor with N+ gate, N+ source/drain, shared silicide contact diode, shadow shallow trench isolation (sSTI) structure, and an associated P-well region.

FIG. 10B shows a top-down view of the transistor, illustrating the placement of STI, N+ gate, shared silicide contact, shadow shallow trench isolation (sSTI), and an associated P-well.

FIG. 10C presents a schematic diagram of an LED pixel driver circuit, where T1 is the switch transistor and T2, with a diode, controls the LED brightness. The diagram shows the connection for a data input, a scan line, and PVDD, illustrating an operation between the NFET transistor with a diode and the LED.

FIG. 11A illustrates a vertical cross-sectional view across cut line AA′ in FIG. 11B of a pixel driver PFET transistor with P+ gate, P+ source/drain, shared silicide contact diode, shadow shallow trench isolation (sSTI) structure, and an associated N-well region.

FIG. 11B shows a top-down view of the transistor, illustrating the placement of STI, P+ gate, shared silicide contact, and an associated N-well.

FIG. 11C presents a schematic diagram of an LED pixel driver circuit, where T1 is the switch transistor and T2, with a diode, controls the LED brightness. The diagram shows the connection for a data input, a scan line, and PVDD, illustrating an operation between the PFET transistor with a diode and the LED.

FIG. 12A illustrates a vertical cross-sectional view across cut line AA′ in FIG. 12B of a pixel driver NFET transistor with N+ gate, N+ source/drain, shared silicide contact diode, dummy N+ gate, and an associated P-well region.

FIG. 12B shows a top-down view of the transistor, illustrating the placement of a dummy gate, N+ gate, shared silicide contact, and an associated P-well.

FIG. 12C presents a schematic diagram of an LED pixel driver circuit, where T1 is the switch transistor and T2, with a diode, controls the LED brightness. The diagram shows the connection for a data input, a scan line, and PVDD, illustrating an operation between the NFET transistor with a diode and the LED.

FIG. 13A illustrates a vertical cross-sectional view across cut line AA′ in FIG. 13B of a pixel driver PFET transistor with P+ gate, P+ source/drain, shared silicide contact diode, dummy P+ gate, and an associated N-well region.

FIG. 13B shows a top-down view of the transistor, illustrating the placement of a dummy gate, P+ gate, shared silicide contact, and an associated N-well.

FIG. 13C presents a schematic diagram of an LED pixel driver circuit, where T1 is the switch transistor and T2, with a diode, controls the LED brightness. The diagram shows the connection for a data input, a scan line, and PVDD, illustrating an operation between the PFET transistor with a diode and the LED.

FIG. 14A illustrates a vertical cross-sectional view across cut line AA′ in FIG. 14B of a pixel driver NFET transistor with N+ gate, N+ source/drain, shared silicide contact diode, resist protection oxide (RPO), and an associated P-well region.

FIG. 14B shows a top-down view of the transistor, illustrating the placement of RPO, N+ gate, shared silicide contact, and an associated P-well.

FIG. 14C presents a schematic diagram of an LED pixel driver circuit, where T1 is the switch transistor and T2, with a diode, controls the LED brightness. The diagram shows the connection for a data input, a scan line, and PVDD, illustrating an operation between the NFET transistor with a diode and the LED.

FIG. 15A illustrates a vertical cross-sectional view across cut line AA′ in FIG. 15B of a pixel driver PFET transistor with P+ gate, P+ source/drain, shared silicide contact diode, resist protection oxide (RPO), and an associated N-well region.

FIG. 15B shows a top-down view of the transistor, illustrating the placement of RPO, P+ gate, shared silicide contact, and an associated N-well.

FIG. 15C presents a schematic diagram of an LED pixel driver circuit, where T1 is the switch transistor and T2, with a diode, controls the LED brightness. The diagram shows the connection for a data input, a scan line, and PVDD, illustrating an operation between the PFET transistor with a diode and the LED.

FIG. 16A illustrates a vertical cross-sectional view across cut line AA′ in FIG. 16B of a pixel driver NFET transistor with N+ gate, N+ source/drain, shared silicide contact diode, dummy N+ gate, and an associated P-well region.

FIG. 16B shows a top-down view of the transistor, illustrating the placement of a dummy N+ gate, N+ gate, shared silicide contact, and an associated P-well.

FIG. 16C presents a schematic diagram of an LED pixel driver circuit, where T1 is the switch transistor and T2, with a diode, controls the LED brightness. The diagram shows the connection for a data input, a scan line, and PVDD, illustrating an operation between the NFET transistor with a diode and the LED.

FIG. 17A illustrates a vertical cross-sectional view across cut line AA′ in FIG. 16B of a pixel driver PFET transistor with P+ gate, P+ source/drain, shared silicide contact diode, dummy P+ gate, and an associated N-well region.

FIG. 17B shows a top-down view of the transistor, illustrating the placement of a dummy P+ gate, P+ gate, shared silicide contact, and an associated N-well.

FIG. 17C presents a schematic diagram of an LED pixel driver circuit, where T1 is the switch transistor and T2, with a diode, controls the LED brightness. The diagram shows the connection for a data input, a scan line, and PVDD, illustrating an operation between the PFET transistor with a diode and the LED.

FIG. 18A illustrates a vertical cross-sectional view across cut line AA′ in FIG. 18B of a pixel driver NFET transistor with N+ gate, N+ source/drain, shared silicide contact diode, RPO, and an associated P-well region.

FIG. 18B shows a top-down view of the transistor, illustrating the placement of resist protection oxide (RPO), N+ gate, shared silicide contact, and an associated P-well.

FIG. 18C presents a schematic diagram of an LED pixel driver circuit, where T1 is the switch transistor and T2, with a diode, controls the LED brightness. The diagram shows the connection for a data input, a scan line, and PVDD, illustrating an operation between the NFET transistor with a diode and the LED.

FIG. 19A illustrates a vertical cross-sectional view across cut line AA′ in FIG. 19B of a pixel driver PFET transistor with P+ gate, P+ source/drain, shared silicide contact diode, RPO, and an associated N-well region.

FIG. 19B shows a top-down view of the transistor, illustrating the placement of resist protection oxide (RPO), P+ gate, shared silicide contact, and an associated N-well.

FIG. 19C presents a schematic diagram of an LED pixel driver circuit, where T1 is the switch transistor and T2, with a diode, controls the LED brightness. The diagram shows the connection for a data input, a scan line, and PVDD, illustrating an operation between the PFET transistor with a diode and the LED.

FIG. 20A illustrates a vertical cross-sectional view across cut line AA′ in FIG. 20B of a pixel driver NFET transistor with N+ gate, N+ source/drain, shared silicide contact diode, mixed cross-coupled diode, dummy N+ gate, and an associated P-well region.

FIG. 20B shows a top-down view of the transistor, illustrating the placement of dummy N+ gate, N+ gate, shared silicide contact, and an associated P-well.

FIG. 20C presents a schematic diagram of an LED pixel driver circuit, where T1 is the switch transistor and T2, with a mixed cross-coupled diode, controls the LED brightness. The diagram shows the connection for a data input, a scan line, and PVDD, illustrating an operation between the NFET transistor with a diode and the LED.

FIG. 20D shows a horizontal cross-sectional view of the transistor across cut line BB′ in FIG. 20A of a pixel driver NFET transistor, illustrating the placement of a mixed cross-coupled diode, Source/Drain, and an associated P-well.

FIG. 20E shows the energy band diagram across cut line CC′ in FIG. 20D of a mixed cross-coupled diode in a pixel driver NFET transistor, illustrating an easy transition of carriers to an N+ region.

FIG. 20F shows the energy band diagram across cut line DD′ in FIG. 20D of a mixed cross-coupled diode in a pixel driver NFET transistor, illustrating a potential barrier (Φ4) of the energy for carriers to surmount.

FIG. 21A illustrates a vertical cross-sectional view across cut line AA′ in FIG. 21B of a pixel driver PFET transistor with P+ gate, P+ source/drain, shared silicide contact diode, mixed cross-coupled diode, dummy P+ gate, and an associated N-well region.

FIG. 21B shows a horizontal cross-sectional view of the transistor, illustrating the placement of a dummy gate, P+ gate, shared silicide contact, and an associated N-well.

FIG. 21C presents a schematic diagram of an LED pixel driver circuit, where T1 is the switch transistor and T2, with a mixed cross-coupled diode, controls the LED brightness. The diagram shows the connection for a data input, a scan line, and PVDD, illustrating an operation between the PFET transistor with a diode and the LED.

FIG. 21D shows a horizontal cross-sectional view of the transistor across cut line BB′ in FIG. 21A of a pixel driver PFET transistor, illustrating the placement of a mixed cross-coupled diode, Source/Drain, and an associated N-well.

FIGS. 21E and 21F illustrate the carrier transport mechanism facilitated by the mixed cross-coupled arrangement of junctions, which may contribute to a high sub-threshold swing.

FIG. 22A illustrates a vertical cross-sectional view across cut line AA′ in FIG. 22B of a pixel driver NFET transistor with N+ gate, N+ source/drain, mixed cross-coupled diode, RPO, and an associated P-well region.

FIG. 22B shows a top-down view of the transistor, illustrating the placement of a mixed cross-coupled diode, RPO, N+ gate, shared silicide contact, and an associated P-well.

FIG. 22C presents a schematic diagram of an LED pixel driver circuit, where T1 is the switch transistor and T2, with a mixed cross-coupled diode, controls the LED brightness. The diagram shows the connection for a data input, a scan line, and PVDD, illustrating an operation between the NFET transistor with a diode and the LED.

FIG. 22D shows a horizontal cross-sectional view of the transistor across cut line BB′ in FIG. 22A of a pixel driver NFET transistor, illustrating the placement of a mixed cross-coupled diode, Source/Drain, and an associated P-well.

FIG. 23A illustrates a vertical cross-sectional view across cut line AA′ in FIG. 23B of a pixel driver PFET transistor with P+ gate, P+ source/drain, shared silicide contact diode, mixed cross-coupled diode, RPO, and an associated N-well region.

FIG. 23B shows a top-down view of the transistor, illustrating the placement of RPO, P+ gate, shared silicide contact, and an associated N-well.

FIG. 23C presents a schematic diagram of an LED pixel driver circuit, where T1 is the switch transistor and T2, with a mixed cross-coupled diode, controls the LED brightness. The diagram shows the connection for a data input, a scan line, and PVDD, illustrating an operation between the PFET transistor with a diode and the LED.

FIG. 23D shows a horizontal cross-sectional view of the transistor across cut line BB′ in FIG. 23A of a pixel driver PFET transistor, illustrating the placement of a mixed cross-coupled diode, Source/Drain, and an associated N-well.

FIG. 24 is a process flow illustrating embodiment method steps to form a pixel driving transistor with a diode having a higher sub-threshold swing according to various embodiments disclosed herein.

FIG. 25 is a process flow illustrating another embodiment method steps to form a pixel driving transistor with a diode having a higher sub-threshold swing according to various embodiments disclosed herein.

FIG. 26 is a process flow illustrating another embodiment method steps to form a pixel driving transistor with a diode having a higher sub-threshold swing according to various embodiments disclosed herein.

FIG. 27 is a process flow illustrating another embodiment method steps to form a pixel driving transistor with a diode having a higher sub-threshold swing according to various embodiments disclosed herein.

FIG. 28 is a process flow illustrating another embodiment method steps to form a pixel driving transistor with a diode having a higher sub-threshold swing according to various embodiments disclosed herein.

FIG. 29 is a process flow illustrating another embodiment method steps to form a pixel driving transistor with a diode having a higher sub-threshold swing according to various embodiments disclosed herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. Generally, all devices of the present disclosure may be rotated unless otherwise specified, and the spatially relative descriptors used herein may likewise be interpreted accordingly. Unless explicitly stated otherwise, each element having the same reference numeral is presumed to have the same material composition and to have a thickness within a same thickness range.

The various embodiments disclosed herein provide solutions to enhance the performance and reliability of pixel drivers in light-emitting diode (LED) and in particular, organic light-emitting diode (OLED) displays. Various embodiments disclosed herein address issues such as narrow operation windows for pixel drivers by achieving high-resolution, high-efficiency LED displays that meet the growing demands of modern display technologies.

Various embodiments disclosed herein are directed to LED pixel driver technology, where precise control of pixel illumination and power efficiency are beneficial for the LED industry. LED displays need pixel drivers that may deliver accurate gray-scale levels and high brightness while maintaining low power consumption. Various embodiments may involve various advanced configurations of transistors and diodes directed to improve sub-threshold swing and overall device performance.

Pixel drivers typically utilize MOSFETs (Metal-Oxide-Semiconductor Field-Effect Transistors) to control the current flowing through LEDs. However, related MOSFET-based pixel drivers may face challenges related to sub-threshold leakage, inconsistent brightness levels, and power inefficiencies. Various embodiments disclosed herein address these challenges by introducing advanced pixel driver structures that incorporate a combination of MOSFETs and diodes in series. . . . Such diodes in series configurations may enhance the sub-threshold swing, providing better control over the LED current and improving display uniformity and efficiency.

Various embodiments disclosed herein include the integration of high sub-threshold swing transistors with a diode to achieve finer control over the current flowing through the LEDs, leading to more accurate brightness and gray-scale controls. This improved control is particularly beneficial in reducing power consumption and increasing the overall efficiency of the display.

In addition to performance improvements, various embodiments disclosed herein offer flexible device and circuit design capabilities for various applications in pixel driver technology. Various embodiments allow for versatile configurations that may be adapted to different display requirements and manufacturing processes without an additional mask and process steps, where the process flows described herein are compatible with a process of records (POR), enabling less process variation and no larger area penalty. This flexibility ensures that the pixel driver designs can be tailored to meet specific performance and integration needs, making them suitable for a wide range of LED display applications.

According to an aspect of the present disclosure, the pixel driver structures may be designed to leverage high sub-threshold swing transistors, which offer advanced controls over carrier transport compared to traditional designs. The integration of advanced transistors in conjunction with diode structures ensures precise control of the LED brightness and gray-scale levels.

The following detailed description, when read in conjunction with the accompanying figures, provides a comprehensive understanding of the various embodiments and features of the present disclosure. The figures are intended to illustrate the aspects of the disclosure, including the advanced pixel structures and the associated energy band diagrams that explain the underlying physics of carrier transport and potential barriers within the device.

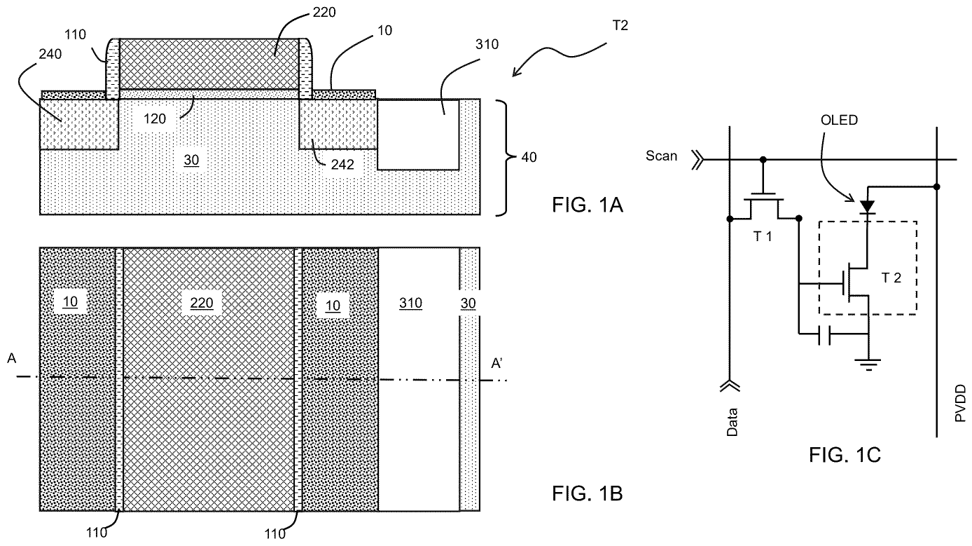

FIGS. 1A-1C illustrate the typical structure and operation of a pixel driver circuit used in LED displays, and in particular OLED displays. The pixel circuit comprises transistors configured to control the current flowing through the LED, thereby regulating its brightness and the gray-scale.

FIG. 1A depicts a first exemplary vertical cross-sectional view of a pixel driver transistor structure, comprising several components such as semiconductor substrate 40, P-well 30, N+ Source 242 and Drain 240, metallic contact (silicide) 10, shallow trench isolation (STI) 310, gate oxide 120 (also referred to as a gate dielectric), spacers 110, and N+ gate electrode 220. In an embodiment, a substrate 40 may be, but is not limited to, a commercially available silicon (Si), germanium (Ge), gallium arsenide (GaAs), silicon carbide (SiC), or gallium nitride (GaN) substrate. Substrate 40 may include a semiconductor material layer at least at an upper portion thereof. The semiconductor material layer may be a surface portion of a bulk semiconductor substrate, or may be a top semiconductor layer of a semiconductor-on-insulator (SOI) substrate. In one embodiment, the semiconductor material layer in substrate 40 may include a single crystalline semiconductor material such as single crystalline silicon.

A substrate 40, as depicted in FIG. 1A, serves as the foundational layer for the pixel driver circuit. Substrate 40 may be doped with various dopants to achieve the desired electrical properties. Doping involves introducing impurities into the semiconductor material to modify the semiconductor material's electrical conductivity. The substrate 40 may be doped with dopants, but is not limited to, such as boron for p-type doping in Si substrate and phosphorous for n-type doping in a silicon (Si) substrate to create P-well 30 and N-well 20 regions, respectively. Other doping elements are within the contemplated scope of disclosure. A doping process typically involves ion implantation and/or diffusion. In ion implantation, dopant ions are accelerated and implanted into the substrate 40 at specific locations. This ion implantation method provides precise control over the doping concentration and depth. Following ion implantation, the substrate 40 may undergo an annealing process and a diffusion process, where the substrate 40 is heated up to 1050° C. to repair damage caused by the implantation and activate the dopants, allowing them to occupy positions in the semiconductor lattice crystal structure. The diffusion process involves placing the substrate 40 in a high-temperature (900° C.-1000° C.) furnace with a dopant source. The dopant diffuses into the substrate over time, creating the desired doping profile. Typical doping concentrations for different regions in semiconductor devices may be achieved by different doses. The doping concentration of an N-well and P-well is typically in a range of 10¹⁶ to 10¹⁷ atoms/cm³. The N+ and P+ regions, which form the source and drain regions of MOSFET transistors and the diode junctions, have much higher doping concentrations, typically in a range of 10¹⁹ to 10²⁰ atoms/cm³ or higher. This method is commonly used for forming junctions. By carefully controlling the doping processes, the electrical characteristics of the substrate 40 may be tailored to optimize the performance of the pixel driver circuit. The resulting P-well 30 and N-well 20 regions render the necessary isolation and enhance the transistor operation, ensuring and efficient control of the LED brightness.

In one embodiment, a substrate 40 may also include a shallow trench isolation (STI) 310. The STI 310 may act to provide junction isolation of diodes and pixel driver circuit configuration. Forming STI 310 may be part of a technique used to isolate different components on a substrate 40, preventing electrical crosstalk and leakage currents between adjacent junctions and devices. The STI 310 regions maintain the integrity and performance of the transistors and diodes within the pixel driver circuit. The STI 310 process begins with the patterning of the substrate 40 using photolithography to define the areas where trenches will be formed. The defined regions are then etched into the substrate 40 to create trenches. Once the trenches are etched, the trenches may be filled with an insulating material, typically silicon dioxide (SiO₂), to form the STI 310 isolation barriers. The filling process may be done using chemical vapor deposition (CVD) or high-density plasma CVD (HD CVD), ensuring that trenches are completely filled without voids. After the trenches are filled with the insulating material, the excess oxide on the surface of the substrate may be removed through a planarization process, often using chemical mechanical polishing (CMP). This step ensures a flat and smooth surface, which is essential for subsequent layers and processes in the fabrication of the pixel driver circuit.

In one embodiment, gate oxide 120 may be a thin insulating layer situated between gate electrode 220 and the semiconductor substrate 40. Gate oxide 120 may comprise silicon dioxide (SiO₂) or high-k dielectric materials but is not limited to, such as aluminum oxide (Al₂O₃), hafnium oxide (HfO₂), zirconium oxide (ZrO₂), or oxynitride (SiON). The fabrication process of the gate oxide begins with thermal oxidation, where the substrate 40 may be exposed to high temperatures in an oxidizing environment to grow a thin oxide layer. Alternatively, chemical vapor deposition (CVD) may be used to deposit high-k dielectrics, which increase the effective dielectric constant and allow further scaling of the transistor dimensions. Gate oxide 120 provides an insulating barrier that controls the flow of charge carriers in a semiconducting channel. The insulating barrier and creation of a semiconducting channel in instances in which a voltage is applied the gate electrode 220 provides the transistors'switching characteristics.

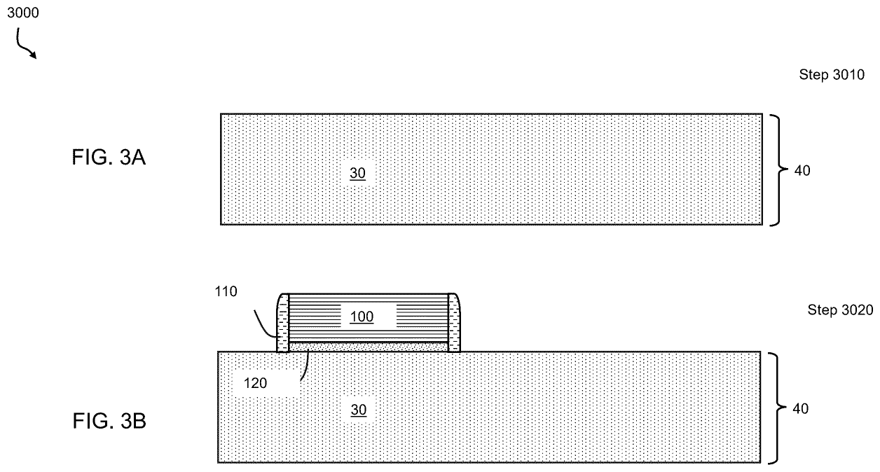

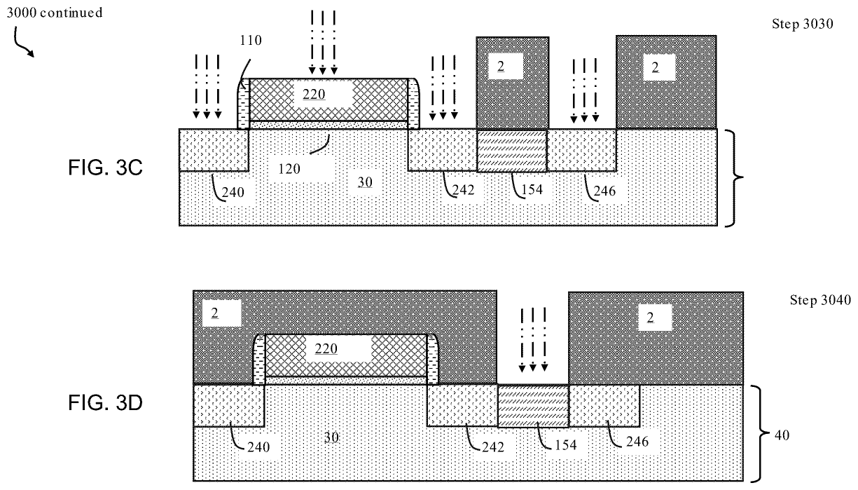

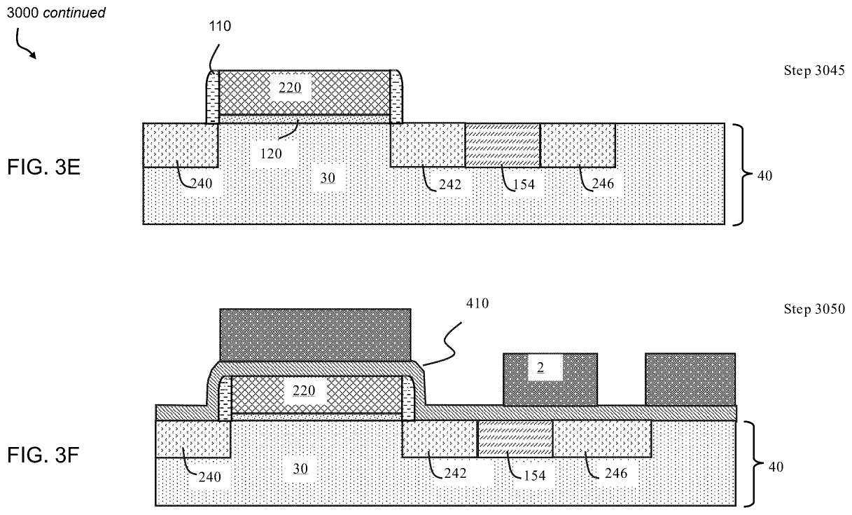

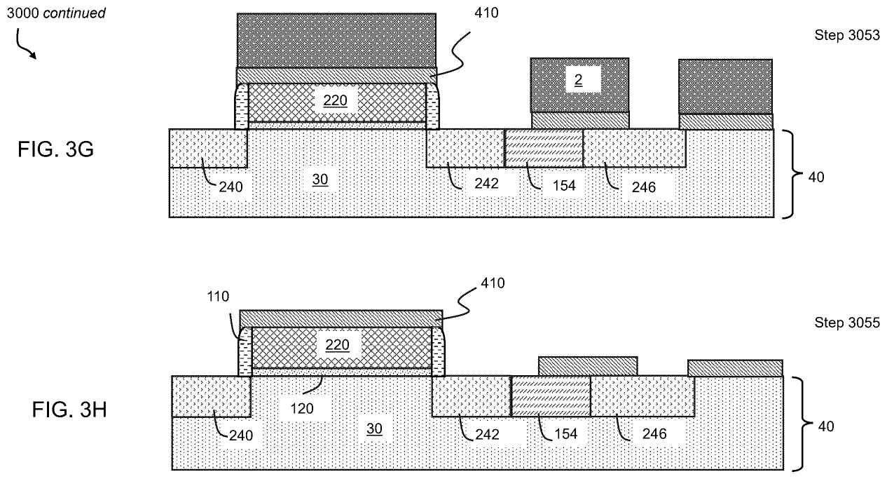

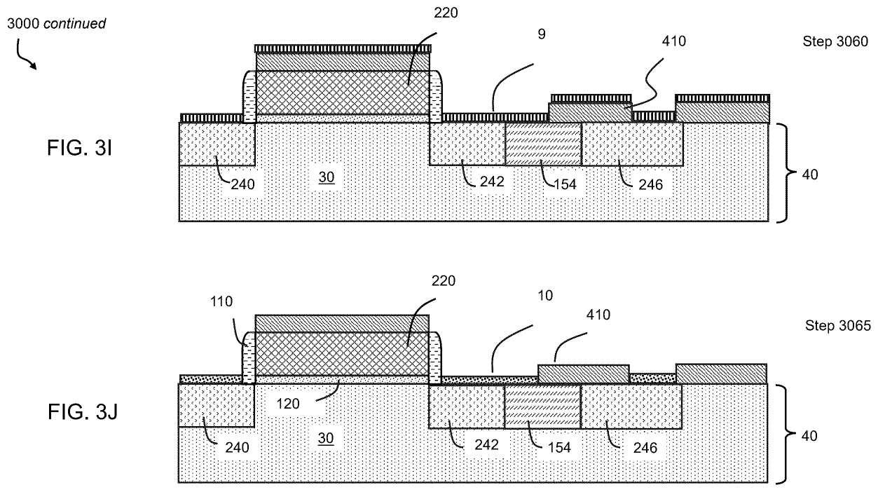

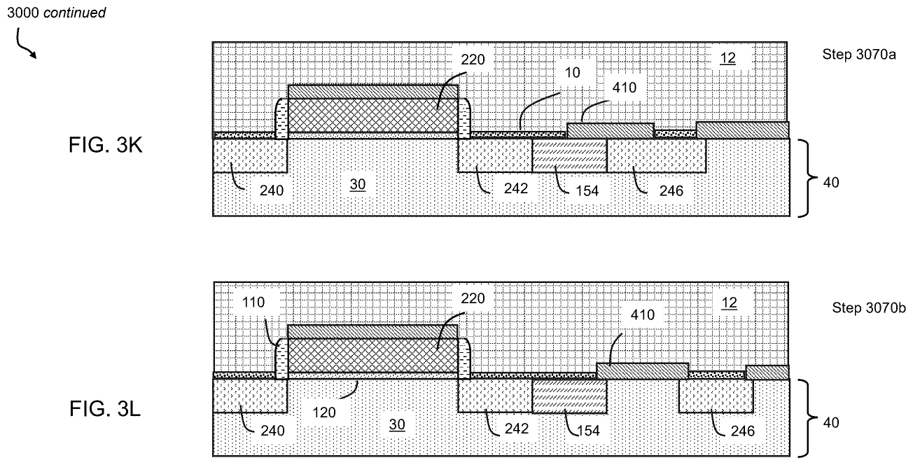

Depending on the desired electrical properties and process requirements, an undoped gate electrode 100 (shown in Step 3020 in FIG. 3B) may comprise a polycrystalline silicon (poly-Si) or a metal gate. For N+ doped poly-Si gates 220, the formation of the gate electrode 100 (shown in FIG. 3B) starts with the deposition of a poly-Si layer over the gate oxide. A poly-Si layer may then be patterned using photolithography techniques and etched to form the gate structure 100. Alternatively, metal gate electrodes 100 may be, but are not limited to, titanium nitride (TiN), tantalum nitride (TaN), or tungsten (W). The choice of gate electrode 100 material impacts the work function and, thus, the threshold voltage of the transistor, impacting circuit performance.

A spacer 110 (shown in FIG. 1A and FIG. 3B) may be formed on the sidewall of gate electrode 100 to define the lateral dimensions of the source 242 and drain 240 extensions. A spacer 110 may further isolate any metallic encroachment by silicide 10 formation, preventing electrical failure in a circuit. A spacer 110 may comprise silicon nitride (Si₃N₄) or silicon dioxide (SiO₂). The formation of spacer 110 may begin with the deposition of a conformal layer of spacer material over the undoped gate electrode structure 100 (shown in FIG. 3) and substrate 40. The spacer material may be etched using an anisotropic etching process, which removes the spacer material from the horizontal surfaces while leaving it on the vertical sidewalls of the undoped gate electrode 100 (shown in FIG. 3). Spacer 110 in FIG. 1A helps to precisely define the source region 242 and drain region 240. Further spacer 110 may act as a mask during the implantation of dopants, ensuring that the dopants are correctly positioned. Source/drain region(s) also referred to as source/drain terminal(s) may refer to a source or a drain, individually or collectively dependent upon the context. In one embodiment, the gate oxide 120, spacer 110, and the N+ gate electrode 220 form the core structure of NFET transistor (shown in FIG. 1A), controlling on/off states and modulating electrical characteristics for various operation conditions. The precise fabrication of these components promotes the reliable operation of a pixel driver circuit, ensuring efficient control of the LED brightness, gray-scale control, and overall display performance.

Source 242 and drain 240 are the two terminals of a NFET transistor between which current flows in instances in which the NFET transistor is turned on. Source/drain region(s) (also referred to as source/drain terminals) may refer to a source terminal or a drain terminal, individually or collectively dependent upon the context. The formation of source/drain regions typically involves the doping of the corresponding semiconductor substrate 40 to create highly conductive junction areas. The process (as illustrated in Step 3030 in FIG. 3C) may include ion implantation, in which dopant ions such as boron for p-type regions (source/drain of PMOSFET) or phosphorus/arsenic for n-type regions (source/drain of NMOSFET) are accelerated into the substrate 40 at predefined locations. Following implantation, an annealing process may be carried out to repair damage to Si lattice of crystal structure and activate the dopants, allowing dopants to integrate properly into the substrate 40. The N+ and P+ regions, which form the source and drain regions of MOSFET transistors and the diode junctions, have doping concentrations, typically in a range of 10¹⁹ to 10²⁰ atoms/cm³ or higher.

Silicide 10 layer in FIG. 1A may be formed on top of source 242 and drain 240 regions to reduce contact resistance and improve current flow and wire nodes in the circuit. Silicide 10 formation begins with depositing thin metal layers 9 (as explained in a step 3060 shown in FIG. 3I), typically comprising titanium, cobalt, or nickel, over the doped source and drain regions. Metal 9 (as explained in step 3060 shown in FIG. 3I) may be deposited over source 242 and drain 240 regions using sputtering or evaporation techniques. Substrate 40 is then subjected to a rapid thermal annealing (RTA) process, rendering metal 9 to react with the silicon substrate 40 and form a metal silicide compound 10. Unreacted metal 9 may be subsequently removed through selective etching, leaving the silicide 10 only in source 242 and drain 240 contact areas behind (as explained in step 3065 shown in FIG. 3J). In one embodiment, source 242, drain 240, and silicide 10 are beneficial for the transistor's operation within the pixel circuit by lowering contact resistance.

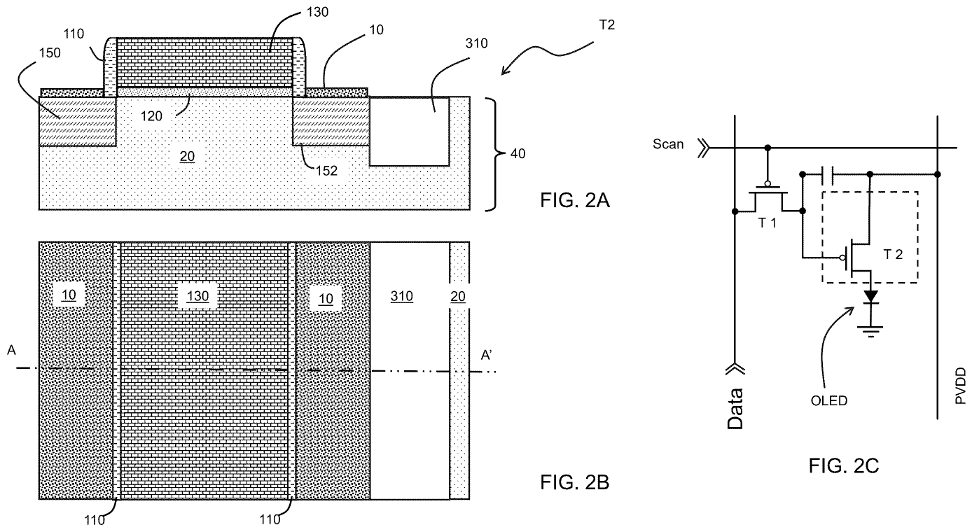

The physics underlying the operation of the pixel driver circuit involves the carrier transport mechanism. In an embodiment in which a NFET is used (as shown in FIG. 1A), electrons are the primary charge carriers. In an instance in which a positive voltage in the range of 1V to 2V is applied to the N+ gate electrode 220, an inversion layer forms within the surface of the Si substrate 40, lowering a barrier height allowing electrons to flow from the source 242 to the drain 240, and turning the NFET transistor on. In an embodiment in which a PFET is used (as shown in FIG. 2A), holes are the primary charge carriers. In instances in which a negative voltage is applied to the P+ gate electrode 130 (as shown in FIG. 2A), an accumulation layer forms within the surface of the Si substrate 40, lowering a barrier height allowing holes to flow from the source 152 to the drain 150, and turning the PFET transistor on (as shown in FIG. 2A).

For pixel driver applications, as illustrated in the schematic circuit diagrams in FIGS. 1C and 2C, a transistor in LED displays may possess attributes to ensure optimal performance, efficiency, and reliability. Firstly, the switching transistor (T1) may need a low sub-threshold swing to enable rapid switching between the on and off states. This rapid switching capability is beneficial for achieving high refresh rates and minimizing motion blur in dynamic images. Rapid switching ensures that each pixel can be quickly activated or deactivated, providing a clear and sharp display, particularly for moving content. Additionally, precise gray-scale control may be beneficial for the pixel-driving transistor (T2), which prefers a high sub-threshold swing to finely control the current flowing through the LED. Precision is beneficial for the LED pixel driver circuits to achieve accurate gray-scale levels, rendering high-quality images and smooth gradient transitions. Proper gray-scale control ensures that the LED display accurately represents various shades and colors, contributing to a more lifelike viewing experience. A pixel-driving transistor (T2) may seek to deliver a high current to the LED to achieve the desired brightness levels. The ability to drive high currents allows for brighter and more vibrant displays, enhancing visibility and overall image quality, especially in well-lit environments. Low leakage current is another attribute for both transistors, ensuring power efficiency and helping prolong the lifespan of the LED display. This ability may be particularly beneficial for battery-operated devices like smartphones and tablets. Scalability and integration are other aspects for ensuring that the design may be adapted for different display sizes and resolutions without large changes to manufacturing processes.

FIG. 1B shows a top view of FIG. 1A, illustrating the layout of the components within the pixel driver circuit. This view helps in understanding the spatial arrangement of silicide 10, N+ gate 220, spacer 110, STI 310, P-well 30, and the integration of different elements in the circuit.

FIG. 1C presents a schematic diagram of the pixel driver circuit. This circuit includes a NFET switching transistor (T1), a NFET pixel-driving transistor (T2), a light-emitting diode (LED) (such as an organic LED (OLED)), a scan line, a data line, and a power supply (PVDD). The pixel driver circuit operates by controlling the current flowing through the LED to adjust brightness and gray-scale control. The operation principle involves the interaction between the switching transistor (T1) and the pixel-driving transistor (T2). In instances in which the scan line activates T1, it allows T1's channel to be conductive. The data line then provides the appropriate voltage to the gate of the pixel-driving transistor (T2) through the conduction path of T1. The pixel-driving transistor (T2) controls the current flowing from power supply (PVDD) through the LED, thereby adjusting the brightness. Power supply (PVDD) may be in the range of 2V to 6V. The current flowing through the LED causes to emit light, and the brightness of the emitted light is proportional to the current controlled by T2.

FIGS. 2A-2C further illustrate an alternate embodiment in the pixel driver circuit structure comprising PFET transistors. Basic functions and operation principles are similar to the description shown in FIGS. 1A-1C.

FIG. 2A shows a vertical cross-sectional view of a pixel driver transistor with components similar to those in FIG. 1A, but with specific modifications to the gate (P+) and junction polarity. For brevity, similar components and method steps that have been discussed above with respect to FIG. 1A may have a shortened description. A PFET pixel-driving transistor may comprise several components such as semiconductor substrate 40, N-well 20, P+ drain 150 and source 152, silicide contact 10, shallow trench isolation (STI) 310, gate oxide 120, spacer 110, and P+ gate electrode 130. Source/drain region(s) (also referred to as source/drain terminal(s)) may refer to a source terminal or a drain terminal, individually or collectively dependent upon the context.

FIG. 2B is a top view of a pixel driver transistor with components similar to those in FIG. 1B, but with specific modifications to the gate (P+) and junction polarity. This view helps in understanding the spatial arrangement of silicide 10, P+ gate electrode 130, spacer 110, STI 310, N-well 20, and the integration of different elements in the circuit.

FIG. 2C presents a schematic diagram similar to FIG. 1C but with adjustment to the gate (P+) and a location of LED, reflecting the variation in design. For brevity, similar components and operation principles that have been discussed above with respect to FIG. 1C may have a shortened description. This circuit has a similar configuration, which includes a PFET switching transistor (T1), a PFET pixel-driving transistor (T2), a light-emitting diode (LED), a scan line, a data line, and a power supply (PVDD). The operation principle is similar to the circuit described above with reference to FIG. 1C.

As described in FIG. 1A-2C, however, a transistor alone may not achieve the desired attributes. Transistors alone may struggle with providing the necessary design flexibility, voltage modulation, and sub-threshold swing modulation without affecting transistor channel doping levels or gate oxide interface state densities, both of which may degrade carrier mobilities and impact current levels and reliability. Adjusting these parameters may negatively impact carrier mobility, leading to lower current drive and potential reliability issues. Thus, transistor-based circuits may be limited in their ability to handle the high current, threshold voltage, and sub-threshold swing of LEDs, leading to potential issues with efficiency and lifespan. Additionally, the linearity and precision control beneficial for accurate color representation and brightness in LED displays may be challenging to achieve with transistors alone. The integration of diodes alongside transistors, as described in the present disclosure, addresses these issues by enhancing design flexibility, increasing sub-threshold swing (S.S.), threshold voltage (Vth) modulation, and ensuring manufacturing compatibility without adding an additional mask, where the process flows disclosed herein are compatible with a process of records (POR).

FIGS. 3A-3L are vertical cross-sectional views of intermediate structures that are formed in an embodiment process flow 3000 of forming a NFET transistor with a diode structure, which enhances the performance and reliability of pixel driver circuits in LED displays. In one embodiment, as shown in FIG. 3K, a layout design of a transistor-diode configuration may include a resist protection oxide (RPO) 410 layer disposed on top of P+ regions 154 and N+ source 246 simultaneously. In another embodiment, as shown in FIG. 3L, a layout design of a transistor-diode configuration may include a resistive protection oxide (RPO) defining P-well 30 as a part of transistor-diode structure in conjunction with N+ region 2466, P+ region 154, and N+ source 242.2 Source/drain region(s) (also referred to as source/drain terminal(s)) may refer to a source terminal or a drain terminal, individually or collectively dependent upon the context.

With reference to the explanation in FIG. 1A, a desired P-well 30 may be formed with the substrate 40 as shown in step 3010 illustrates in FIG. 3A. Substrate 40 may undergo initial cleaning and surface treatment to ensure it is prepared for doping processes, where P-well or N-well regions are formed.

In FIG. 3B (step 3020), the gate oxide layer 120 may be formed over substrate 40. Following gate oxide formation, the undoped gate electrode 100 and spacer 110 may be formed by patterning and anisotropic etch process as described in FIG. 1A. In addition, spacers 110 may be deposited and patterned.

With reference to FIG. 3C, the formation of N+ junction area by ion implantation is illustrated in step 3030. A photoresist layer 2 may be deposited and patterned using photolithography techniques. These photolithography techniques may be used to define the regions where the dopant ions, such as phosphorus (P) or arsenic (As), are to be implanted. The implantation process may introduce these dopants into substrate 40 to form a highly conductive N+ source 246, N+ region 242, and drain 240 regions. Similarly, undoped gate electrode 100 is doped simultaneously, forming N+ gate electrode 220. The photoresist layer 2 may prevent dopant ions from being implanted in the areas located below the patterned photoresist layer 2. Following the ion implantation process, the photoresist material layer 2 may be removed by ashing or through dissolution.

In an embodiment in which PFET is processed (not shown in a process flow 3000, see e.g., FIGS. 2A, 9A, 11A, 13A, 15A, 17A, 19A, 21A, 23A), the process illustrated in FIGS. 3A-3L may involve the different polarity of well and junction formation by ion implantation. Photolithography may be used to define the regions where the dopant ions, such as boron (B) or boron fluoride (BF₂), are to be implanted. In contrast to the N+ region 242, P+ region 154, and N+ source 246 formed in a NFET, the implantation process to form a PFET may introduce dopants into the substrate 40 to form a highly conductive P+ source 156, P+ region 152, and drain 150 regions. Similarly, undoped gate electrode 100 may be doped simultaneously, forming P+ gate electrode 130. For brevity, similar components and method steps that have been discussed above with respect to NFET may have a shortened or omitted description for PFET.

With reference to FIG. 3D, the formation of P+ junction area in NFET is illustrated in step 3040. A photoresist layer 2 may be deposited and patterned using photolithography techniques. These photolithography techniques may be used to define the regions where the dopant ions, such as boron or born fluoride ions may be introduced into substrate 40 to create the P+ regions 154. Similar to the N+ junction formation, photolithography defines the area for implantation. The photoresist material layer 2 may be removed by ashing or through dissolution.

Steps 3045, 3050, 3053, 3055, 3060, 3065, and 3070 are common process steps for all NFET and PFET process flows, 3000, 4000, 5000, 6000A, 6000B, and 7000.

Referring to FIG. 3E, step 3045 is shown in which the intermediate device is exposed to increased temperatures in an annealing process after photoresist stripping and cleaning. The annealing process activates the dopants and repairs the ion implantation-induced damage.

Referring to FIG. 3F, step 3050 is shown in which the deposition and patterning of the resist protection oxide (RPO) 410 are processed. The RPO 410 may be deposited over the entire surface of the substrate 40 and then patterned using photolithography to define the areas for subsequent silicidation. A photoresist material layer 2 may be deposited and then using photolithography techniques patterned and etched to remove the portions of photoresist material layer to expose the position and location of RPO 410 material to remove. This patterning ensures that silicide formation occurs only in the desired regions, thereby protecting other parts of the device from unwanted metal diffusion.

Referring to FIG. 3G, step 3053 is shown in which a wet etchant, such as diluted hydro-fluoric acid (DHF), removes RPO 410 exposed by resist patterning.

In FIG. 3H, step 3055 is shown in which a photoresist strip and clean are performed.

Referring to FIG. 3I, step 3060 is shown in which a metal 9 may be deposited through physical vapor deposition (PVD) sputtering or evaporation by which anisotropic, non-conformal deposition may occur on the horizontal surface. Silicide metal 9 may be deposited over the source and drain regions. This step involves depositing thin layers of metal 9, such as titanium, cobalt, or nickel, which will react with the silicon during a rapid thermal annealing (RTA) process to form a metal silicide compound 10 (shown at step 3065).

Referring to FIG. 3J, step 3065 is shown in which a substrate 40 may be then subjected to a rapid thermal annealing (RTA) process, rendering the metal to react with the silicon substrate and form a metal silicide compound 10. Unreacted metal 9 may be subsequently removed through selective etching, leaving the silicide 10 only in the source 242 and drain 240 contact areas behind.

Referring to FIGS. 3K and 3L, step 3070 involves the deposition of a thick oxide layer 12 for further integration of the device.

In one embodiment, FIG. 3K illustrates a transistor-diode configuration with a resist protection oxide (RPO) 410 layer located on top of regions 154 and 246 simultaneously. This arrangement enhances isolation and protects these regions from electrical interference, ensuring stable operation.

In another embodiment, FIG. 3L presents an alternative transistor-diode arrangement where the RPO 410 defines the P-well 30 as part of the diode structure, in conjunction with regions 242, 154, and 246.

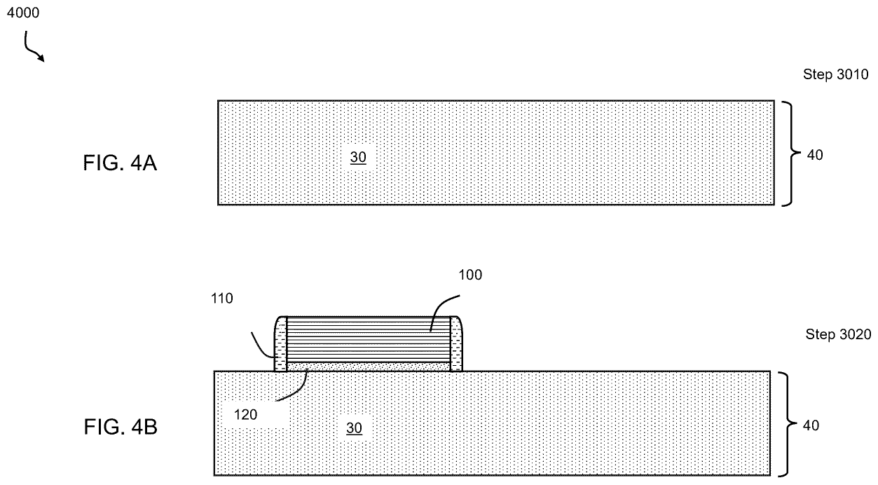

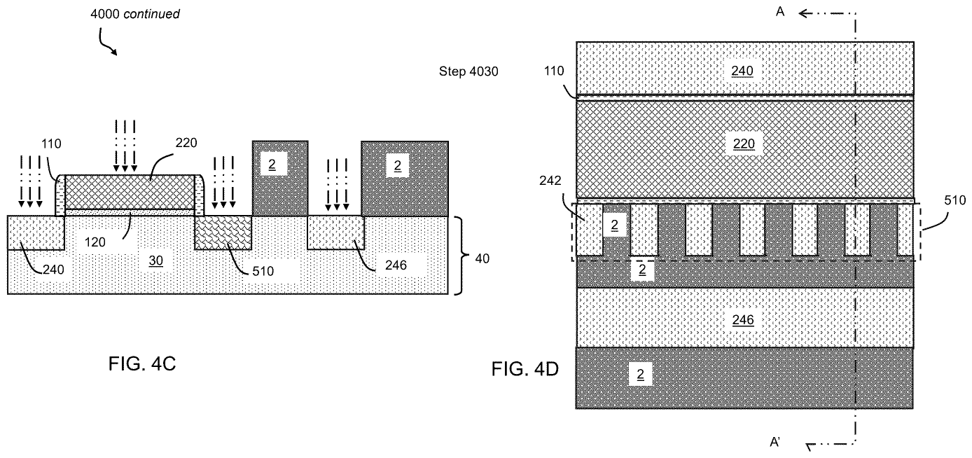

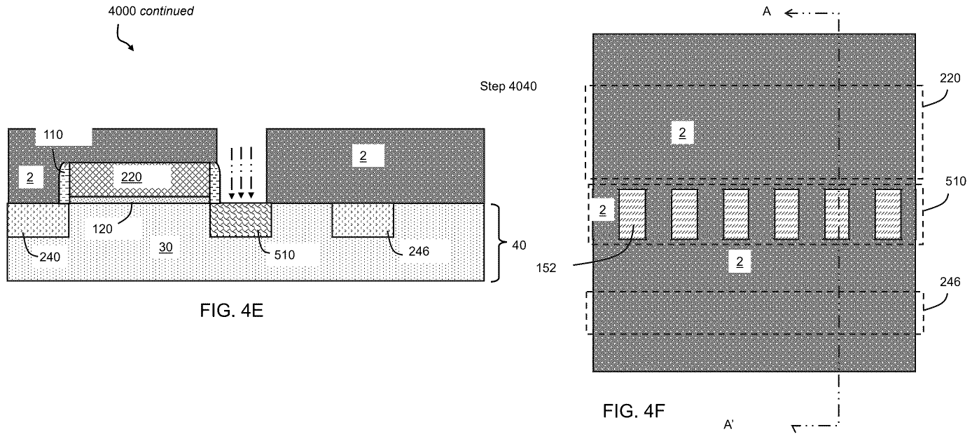

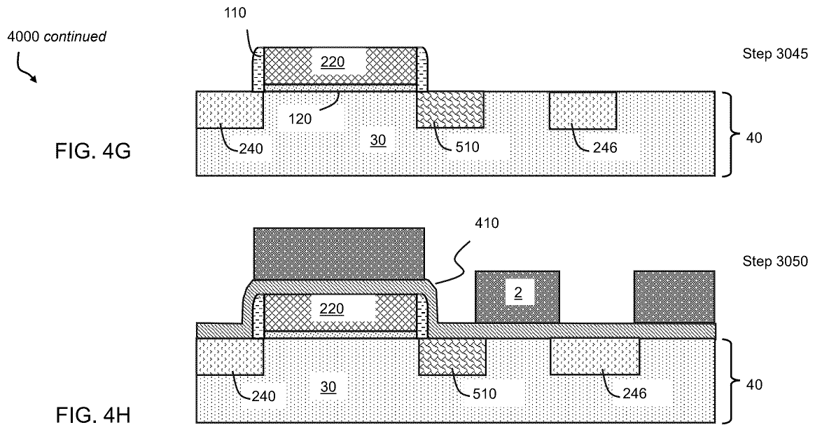

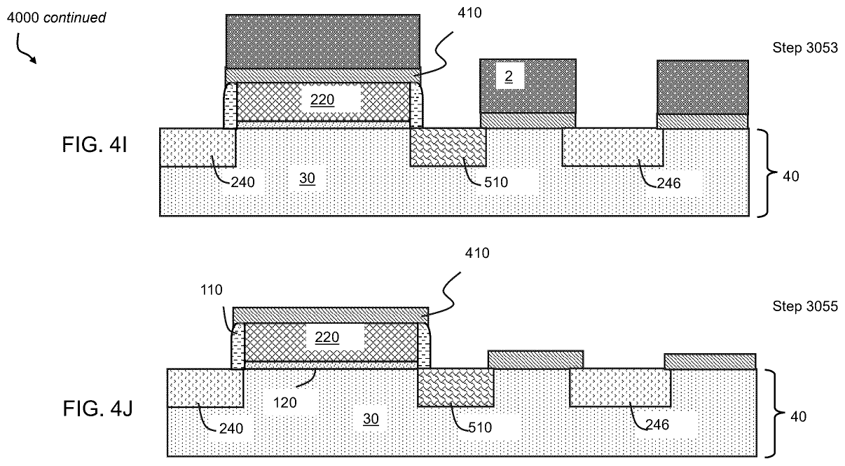

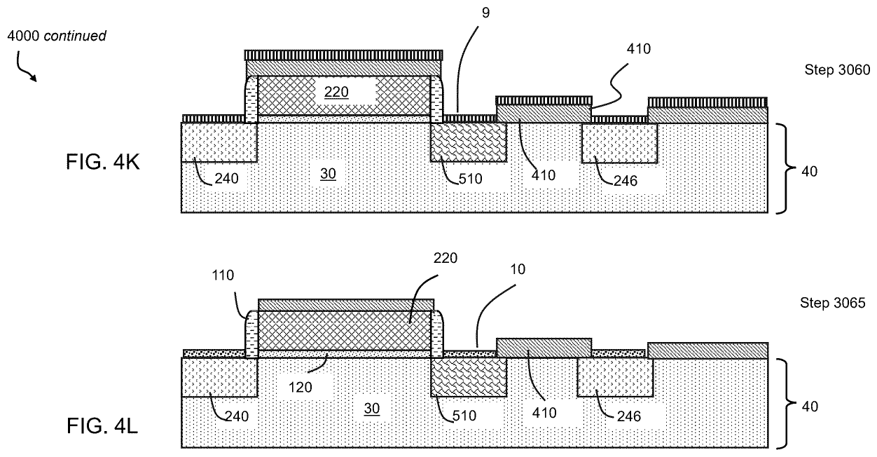

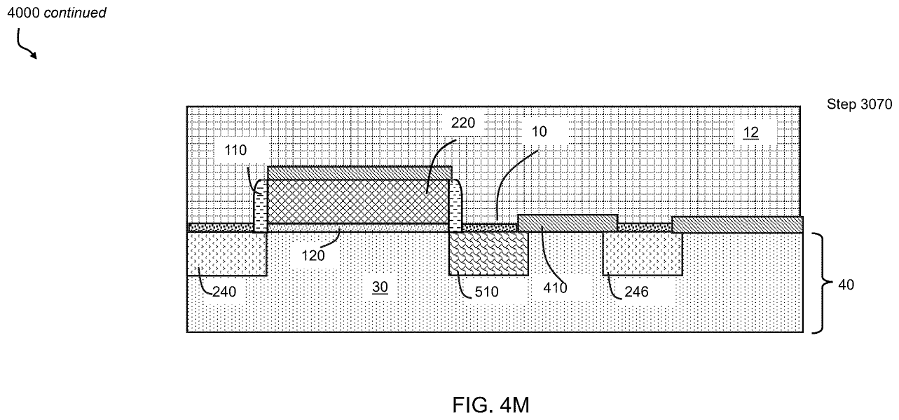

With reference to FIGS. 4A-4M, an alternative embodiment process flow 4000 illustrates the method steps for forming advanced NFET pixel driver transistor structure with mixed cross-coupled diode 510 configurations to enhance the performance and reliability of pixel driver circuits in LED displays. For brevity, similar components and method steps that have been discussed above with respect to FIGS. 3A-3L and process flow 3000 may have a shortened description. Referring to FIG. 4A, step 3010 illustrates the preparation of substrate 40, involving cleaning and doping to form the P-well 30, as previously described in FIG. 3A. Referring to FIG. 4B, step 3020 illustrates processes in which gate oxide 120, undoped gate electrode 100, and spacer 110 may be formed over a substate 40 by deposition, patterning, and etching as detailed earlier in FIGS. 1A and 3B.

With reference to FIGS. 4C and 4D, step 4030 involves the N+ ion implantation process in NFET, where FIG. 4C illustrates a vertical cross-sectional view across cut line AA′ in FIG. 4D. FIG. 4D is a top down view of FIG. 4C. A photoresist material layer 2 that has been patterned through photolithography defines the regions where N+ dopant ions, such as phosphorus or arsenic, are to be implanted. Area 510, referred to as the mixed cross-coupled diode, has an alternating pattern of openings in a photoresist material layer 2 that expose only the area of the N+ region within area 510, as shown in FIG. 4D. This ensures that the N+ source 246, N+ 242 within 510 area, N+ drain 240 region are accurately formed. FIG. 4D shows area 510, the mixed cross-coupled diode, with resist pattern opening the area of the N+ region 242.

With reference to FIG. 4E, step 4040 illustrates processes in which the separate P+ ion implantation process in NFET occurs within area 510. During this step, a separate photoresist material layer 2 that has been patterned using photolithography techniques may be used to open only the regions where P+ dopant ions, such as boron, are to be implanted, as depicted in FIG. 4F. FIG. 4E illustrates a vertical cross-sectional view across cut line AA′ in FIG. 4F. With reference to FIGS. 4G-4M, steps 3045, 3050, 3053, 3055, 3060, 3065, and 3070 are common steps in all process flows and the repetition of steps in process flow 3000.

In an embodiment in which PFET is processed, all of the steps performed in process flow 4000 to form a NFET are similarly performed but with different doping polarity. In an instance in which components of NFET may be designed to have P-well 30, N+ gate electrode 220, N+ source 246, N+ drain 240, and N+/P+ region, PFET may have N-well 20, P+ gate electrode 130, P+ source 156, P+ drain 150, and P+/N+ region, respectively. For example, step 3010 in process flow 4000 may have phosphorous (P) implantation to substrate 40, forming N-well 20. All other components of polarity may be converted by changing ion plantation species from arsenic (As) or phosphorous (P) to boron (B) or boron fluoride (BF₂). For brevity, similar components and method steps that have been discussed above with respect to NFET may have a shortened or omitted description for PFET.

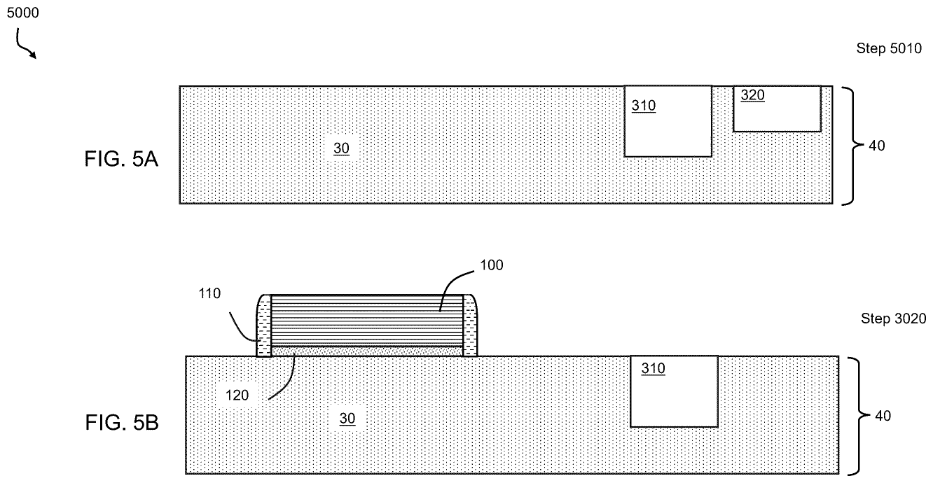

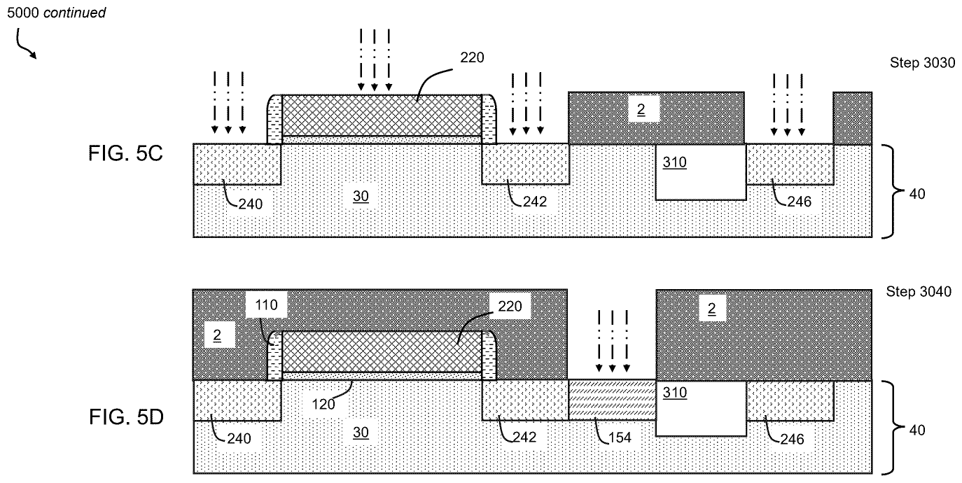

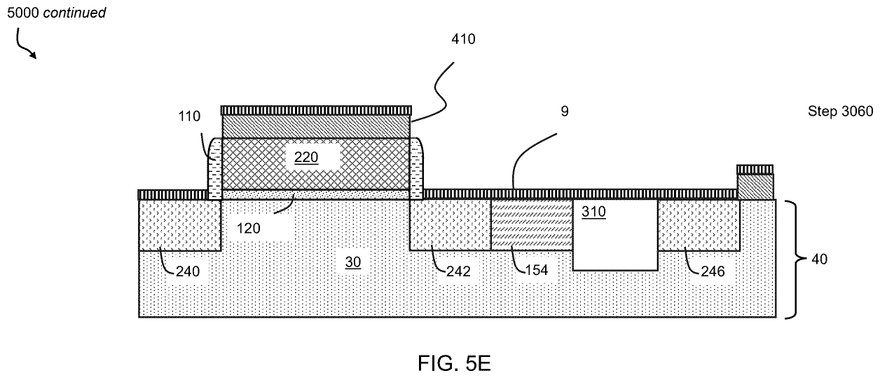

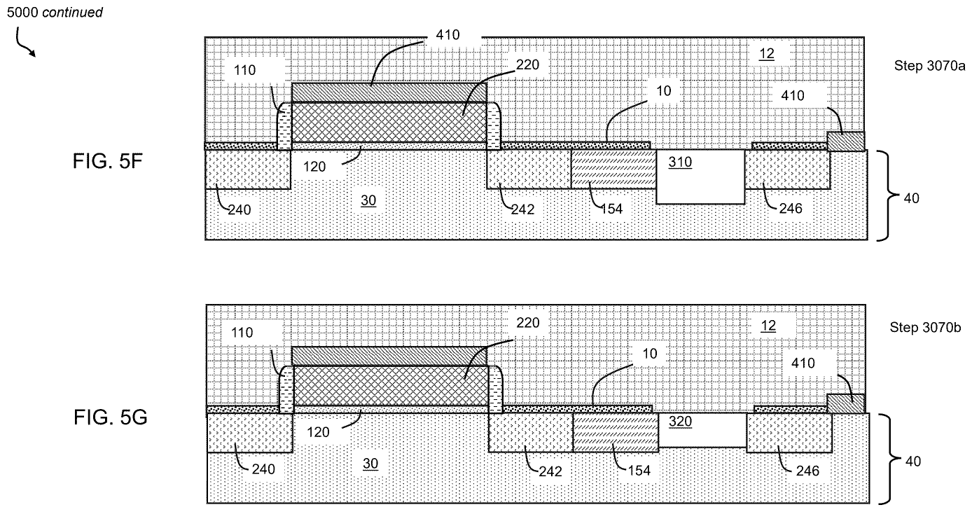

With reference to FIGS. 5A-5G, an alternative embodiment process flow 5000 illustrates the method steps for forming an advanced NFET pixel driver transistor structure with a device design variation that incorporates shallow trench isolation (STI) 310 or shadow STI 320 to further optimize device performance.

With reference to FIG. 5A, step 5010 illustrates the preparation of substrate 40, involving cleaning and doping to form the P-well 30, as previously described in FIG. 3A and process flow 3000. Unlike earlier descriptions in FIG. 3A and 3000, step 5010 includes the formation of shallow trench isolation (STI) regions 310 or 320 to isolate different diode components and use a part of P-well 30 as a diode structure, such that a use of shallow trench isolation (STI) in a transistor-diode structure works similarly to resist protection oxide (RPO) application in FIG. 3L. For brevity, similar components and process principles that have been discussed above with respect to FIGS. 1A, 3A-3L, and a process flow 3000 may have a shortened description. Referring to FIGS. 5B-5G, steps 3020 to 3070 repeat the processes described in FIGS. 3B-3L.

In an embodiment in which shallow trench isolation (STI) structures are used, FIG. 5F illustrates a transistor-diode structure including STI 310, while FIG. 5G illustrates a shadow STI 320, and a part of P-well 30 as a transistor-diode structure.

In embodiments in which PFET is processed, all process flows of 5000 are similarly applied but with different doping polarity as shown in transistor-diode structures 2015 and 2025. In an instance in which components of NFET may be designed to have P-well 30, N+ gate electrode 220, N+ source 246, N+ drain 240, and N+/P+ diode, PFET may have N-well 20, P+ gate electrode 130, P+ source 156, P+ drain 150, and P+/N+ diode, respectively. For example, step 5010 in process flow 5000 may have phosphorous (P) implantation to substrate 40, forming N-well 20. All other components of polarity may be converted by changing ion plantation species from arsenic (As) or phosphorous (P) to boron (B) or boron fluoride (BF₂). For brevity, similar components and method steps that have been discussed above with respect to NFET may have a shortened or omitted description for PFET.

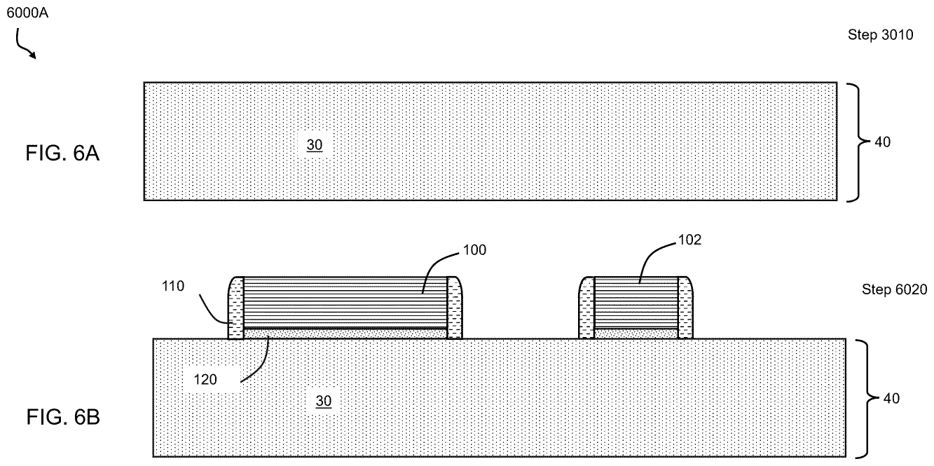

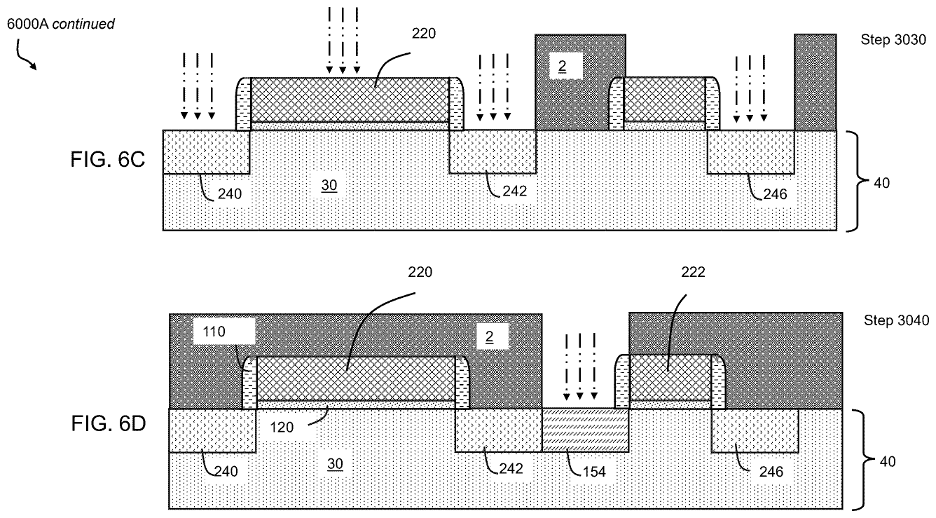

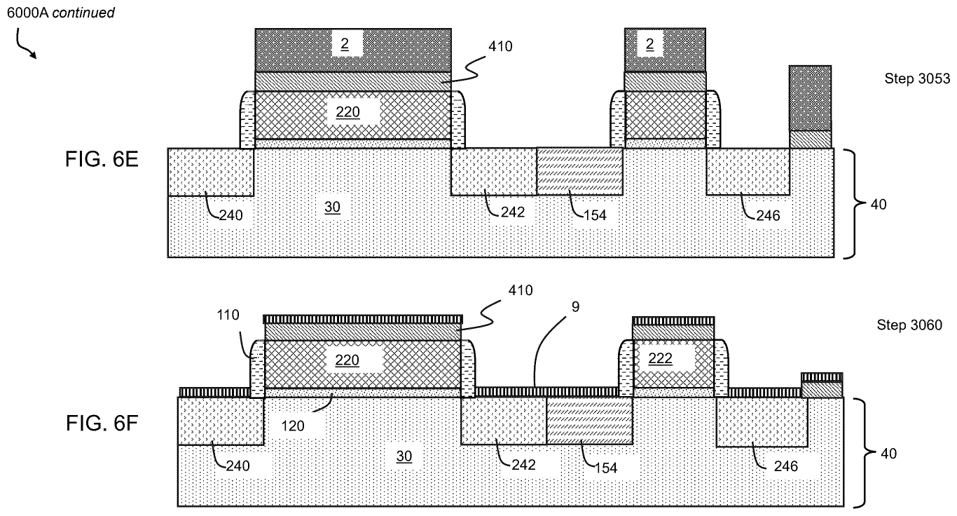

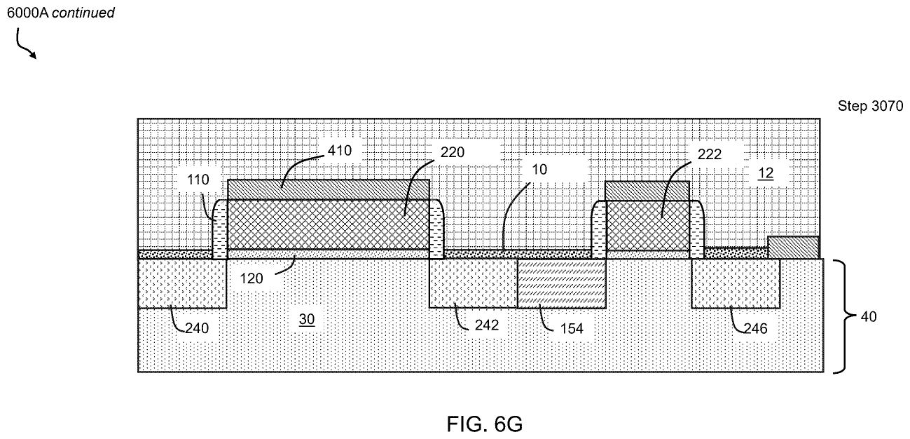

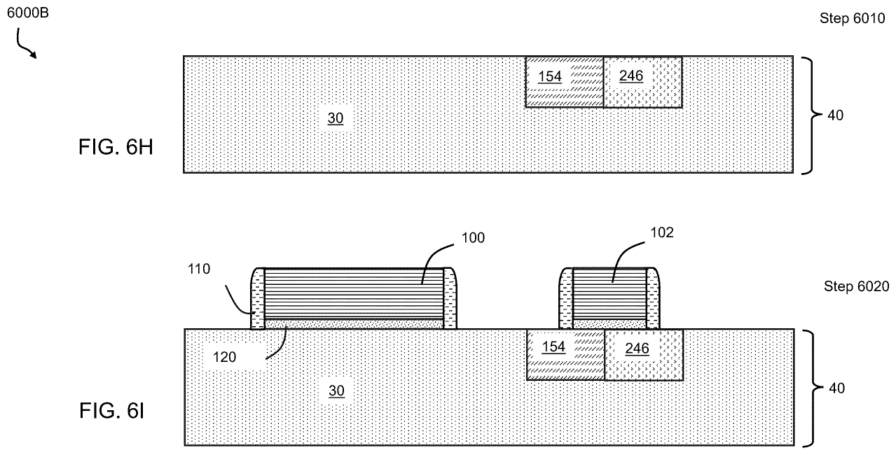

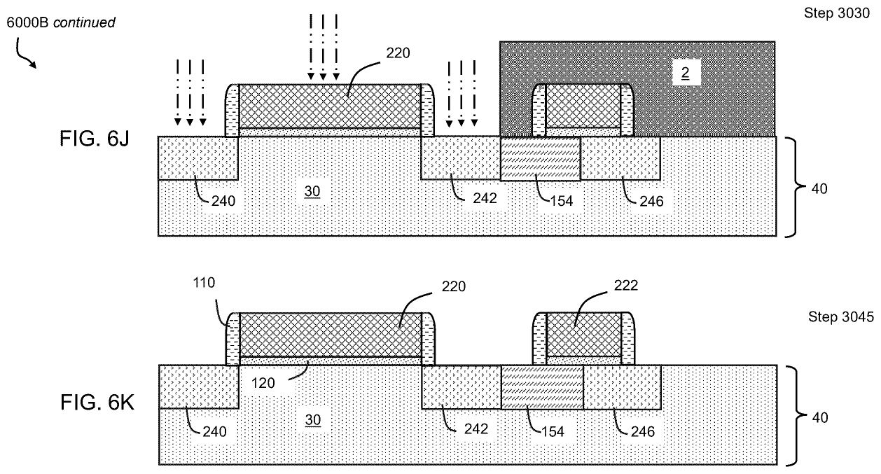

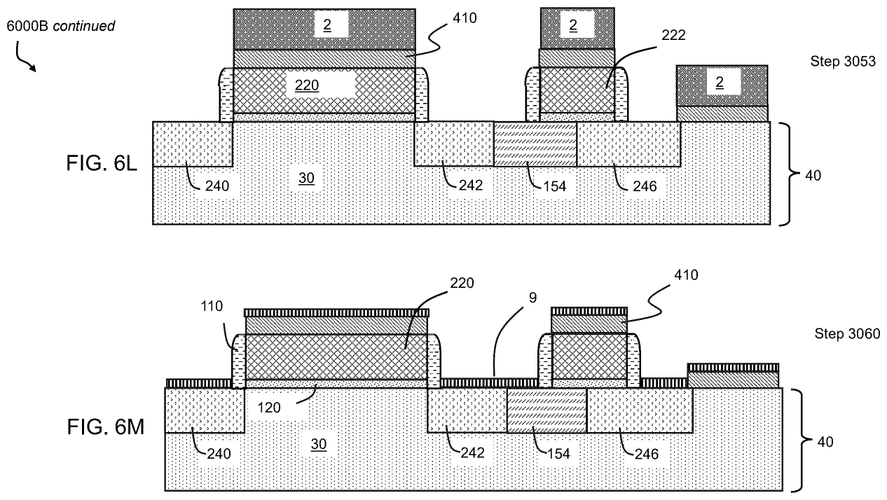

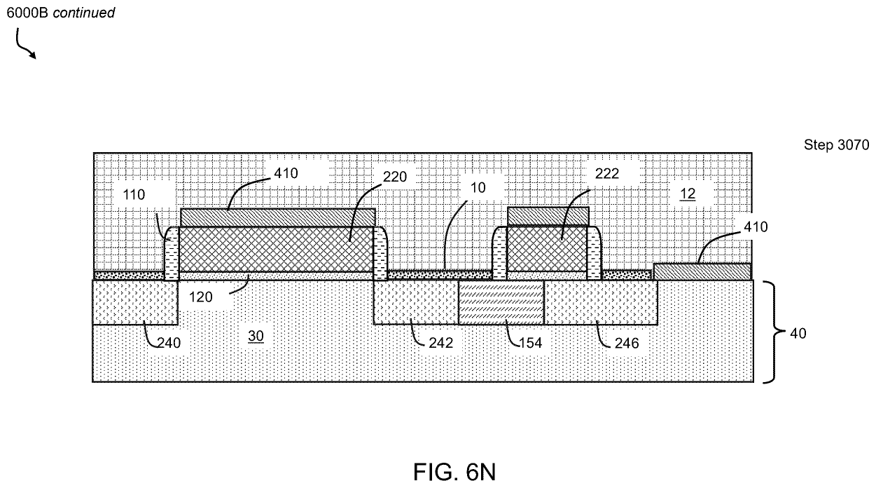

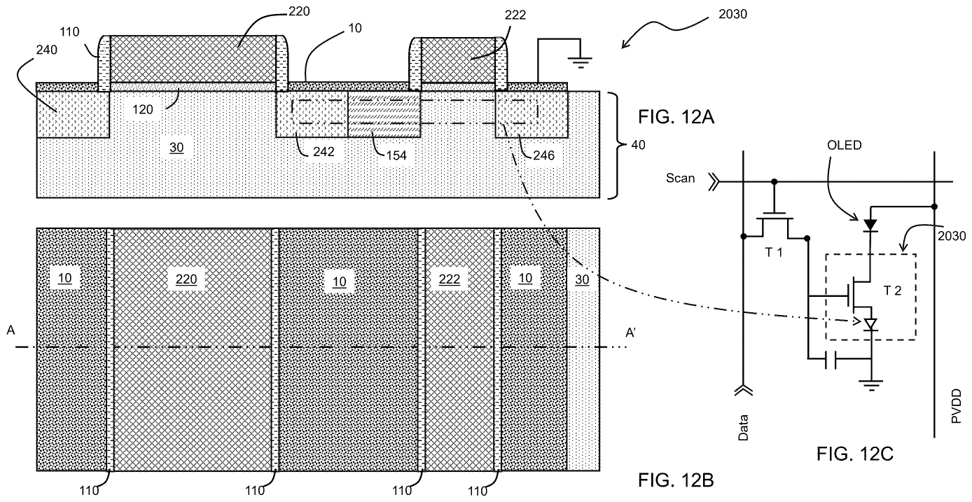

With reference to FIGS. 6A-6G, a process flow 6000A illustrates the alternative embodiment method steps for forming an advanced NFET pixel driver transistor structure with a device design variation that incorporates a dummy N+ gate 222 defining a part of P-well as a transistor-diode structure 2030 as shown in FIG. 12. Referring to FIG. 6A, step 3010 illustrates the preparation of substrate 40, involving cleaning and doping to form the P-well 30, as previously described in FIG. 3A and a process flow 3000.

With reference to FIG. 6B, step 6020 illustrates a process in which an undoped gate electrode 100 and an undoped dummy gate 102 may be formed simultaneously. An undoped dummy gate 102 may be converted to N+ doped dummy gate 222 at step 3030, defining underlying diode area of P-well 30 and source 246 by masking ion implantation, and rendering separate silicide contact on drain 246, such that a use of a dummy gate 102 in a transistor-diode structure works similarly to resist protection oxide (RPO) application in FIG. 3L. For brevity, similar components and process principles that have been discussed above with respect to FIGS. 1A, 3A-3L, and a process flow 3000 may have a shortened description. Referring to FIGS. 6C-6G, steps 3030 to 3070 repeat the processes described in FIGS. 3C-3L.

In an embodiment in which N+ dummy gate 222 is placed over P-well 30, providing separate silicide contact on N+ source 246, FIG. 6G illustrate a transistor-diode structure with an N+ dummy gate 222 and a part of P-well 30 as a diode structure, such that electrons from source 246, when gate electrode 220 is biased (1V˜2V) to open, see gradual resistance changes through P-well and P+ region 154, achieving high sub-threshold swing.

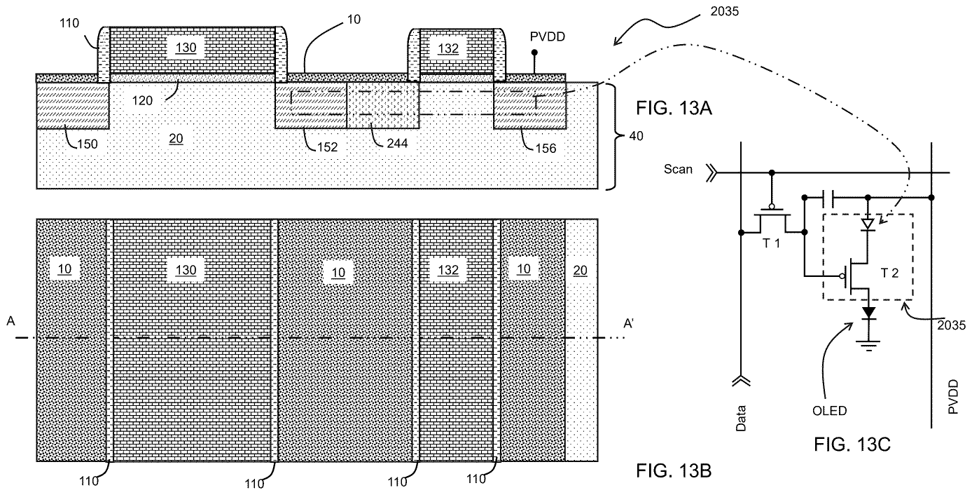

In embodiments in which PFET is processed, all process flows of 6000A are similarly applied but with different doping polarity as shown in a transistor-diode structure 2035 in FIG. 13A. In an instance in which components of NFET may be designed to have P-well 30, N+ gate electrode 220, N+ source 246, N+ drain 240, and N+/P+ diode, PFET may have N-well 20, P+ gate electrode 130, P+ source 156, P+ drain 150, and P+/N+ diode, respectively. For example, step 3010 in process flow 6000 may have phosphorous (P) implantation to substrate 40, forming N-well 20. All other components of polarity may be converted by changing ion plantation species from arsenic (As) or phosphorous (P) to boron (B) or boron fluoride (BF₂). For brevity, similar components and method steps that have been discussed above with respect to NFET may have a shortened or omitted description for PFET.

Referring to FIGS. 6H-6N, another embodiment process flow 6000B illustrates the method steps for forming an advanced NFET pixel driver transistor structure with a device design variation that incorporates early-stage junction implantation enabling the junction areas placed below the N+ dummy gate 222, such that N+ dummy gate 222 is designed to isolate metallic silicide formation while protecting a junction boundary between P+ region 154 and N+ source 246. A transistor-diode structure as shown in FIG. 6N illustrates a separate contact formation on source 246 and a junction protection between P+ region 154 and N+ source 246 by N+ dummy gage 222.

Referring to FIG. 6H, step 6010 illustrates the preparation of substrate 40, involving cleaning and doping to form the P-well 30, as previously described in FIGS. 1 and 3. This step includes the formation of junction areas 154 and 246, which are implanted with patterning steps, before an undoped dummy gate 102 is formed. This early-stage implantation ensures that the junctions are correctly positioned beneath the dummy gate structure, such that source 246 has separate silicide contact by a N+ dummy gate 222.

Referring to FIG. 6I, step 6020 illustrates an undoped gate electrode 100 and an undoped dummy gate 102 are formed simultaneously, wherein the undoped dummy gate 102 is formed over the junction areas between 154 and 246. Referring to FIG. 6J, step 3030 illustrates N+ source/drain implantation as described in FIG. 3C. Referring to FIG. 6K, step 3045, as described in FIG. 3E, is the common cleaning and annealing step for all process flows, 3000, 4000, 5000, 6000A, 6000B, and 7000, to achieve dopant activation and diffusion. With reference to FIGS. 6K-6N, steps 3045 to 3070 repeat the processes described in FIGS. 3E-3L. FIG. 6N shows a transistor-diode structure 2050, including an N+ dummy gate 222 protecting the junction boundary between P+ region 154 and source 246 and achieving separate silicide contact on source 246, such that electrons from source 246, when gate electrode 220 is biased (1V˜2V) to open, see gradual resistance changes through P+ region 154, achieving high sub-threshold swing.

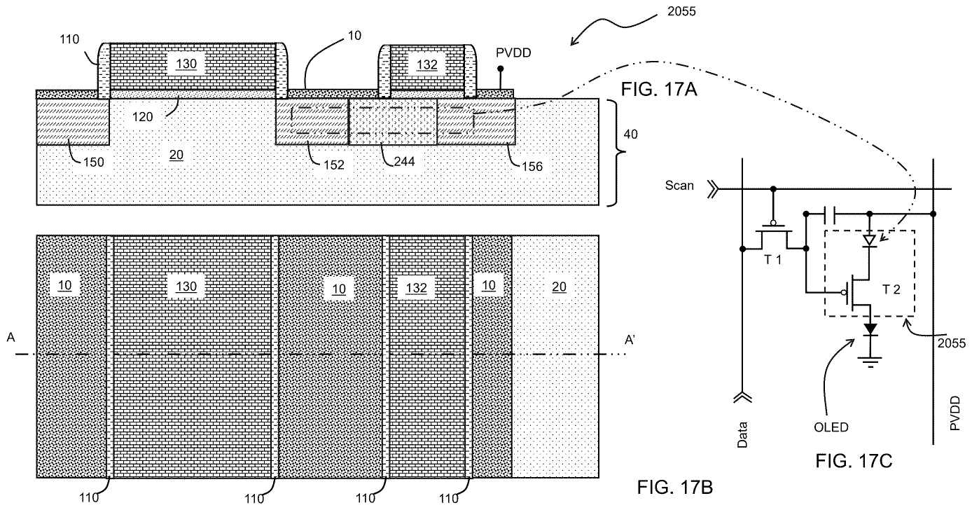

In embodiments in which PFET is processed, all process flows of 6000B are similarly applied but with different doping polarity as shown in a transistor-diode structure 2055 in FIG. 17A. In an instance in which components of NFET may be designed to have P-well 30, N+ gate electrode 220, N+ source 246, N+ drain 240, and N+/P+ diode, PFET may have N-well 20, P+ gate electrode 130, P+ source 156, P+ drain 150, and P+/N+ diode, respectively. For example, step 6010 in process flow 6000 may have phosphorous (P) implantation to substrate 40, forming N-well 20. All other components of polarity may be converted by changing ion plantation species from arsenic (As) or phosphorous (P) to boron (B) or boron fluoride (BF₂). For brevity, similar components and method steps that have been discussed above with respect to NFET may have a shortened or omitted description for PFET.

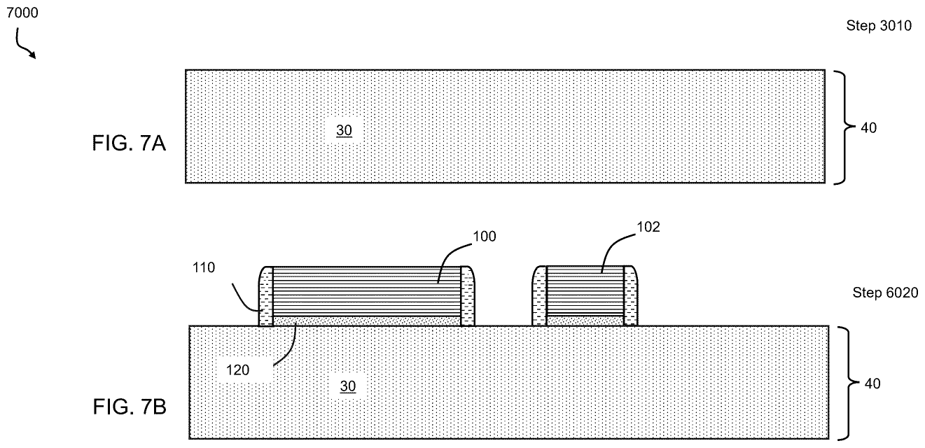

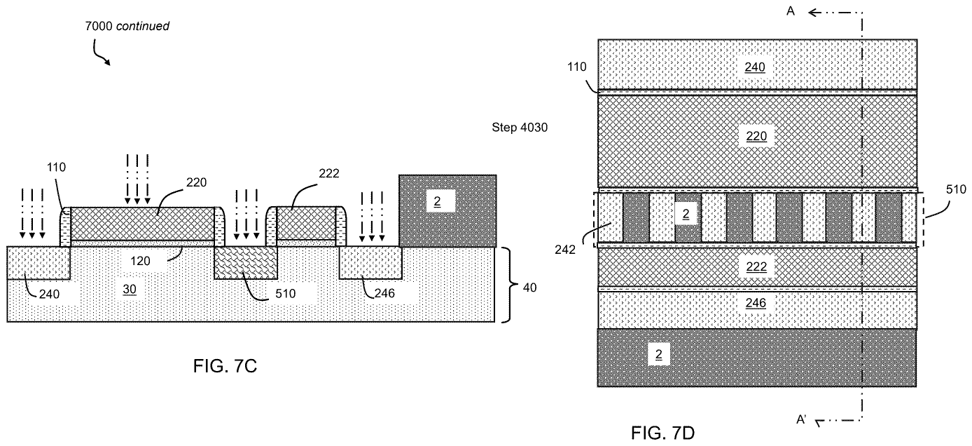

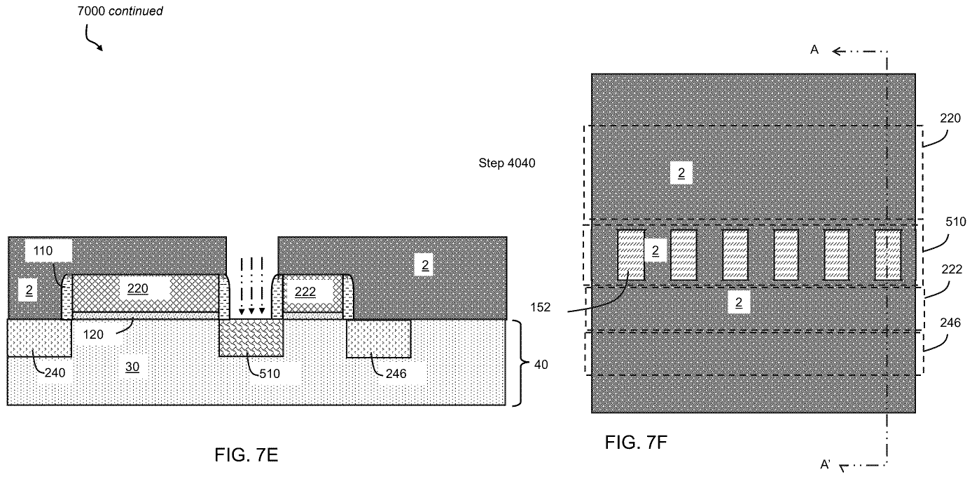

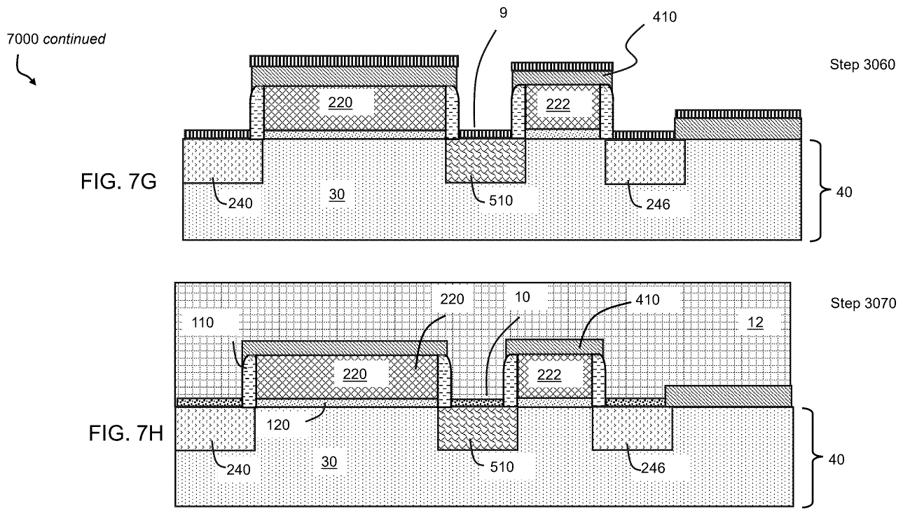

With reference to FIGS. 7A-7H, an alternative embodiment process flow 7000 illustrates the method steps for forming an embodiment of advanced NFET pixel driver transistor structure with a device design variation that incorporates a mixed cross-coupled diode 510 and a N+ dummy gate 222 defining a part of P-well as a diode structure. Referring to FIG. 7A, step 3010 illustrates the preparation of substrate 40, involving cleaning and doping to form the P-well 30, as previously described in FIGS. 1A and 3A. Referring to FIG. 7B, step 6020 illustrates an undoped gate electrode 100 and an undoped dummy gate 102 are formed simultaneously. FIG. 7C at step 4030 illustrates a vertical cross-sectional view across cut line AA′ in FIG. 7D, involving the N+ ion implantation process. A photolithography defines the regions where N+ dopant ions, such as phosphorus or arsenic, are to be implanted. Region 510, referred to as the mixed cross-coupled diode, has a resist 2 pattern opening that exposes only the area of the N+ region within 510, as shown in FIGS. 4D and 7D. This ensures that N+ source 246, N+ 242 in the 510, and N+ drain 240 regions are accurately formed. FIG. 7D shows a top-down view of FIG. 7C. detailing region 510 of a mixed cross-coupled diode, with a resist pattern opening the area of the N+ region 242. FIG. 7E at step 4040 illustrates a vertical cross-sectional view across cut line AA′ in FIG. 7F, involving P+ ion implantation process. During this step 4040, photolithography and resist 2 patterning may be used to open only the regions where P+ dopant ions, such as boron, are to be implanted, as depicted in FIG. 4F and FIG. 7F. Referring to FIGS. 7G and 7H, steps 3060 to 3070 are the repetition of steps described in FIGS. 3I-3K. FIG. 7H at step 3070 shows a transistor-diode structure with an N+ dummy gate 222 protecting and defining P-well in conjunction with mixed cross-coupled diode 510, and achieving separate silicide contact on source 246, such that carriers (electrons) from source 246, when gate electrode 220 is biased (1V˜2V) to open, move sequentially through P-well 30 and region 510, surmounting energy barrier heights, resulting in gradual switching and high sub-threshold swing.

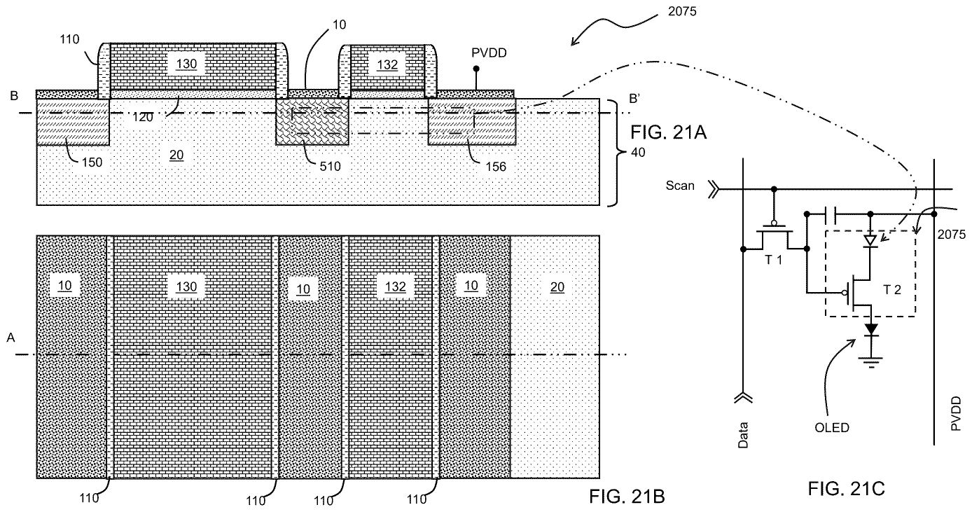

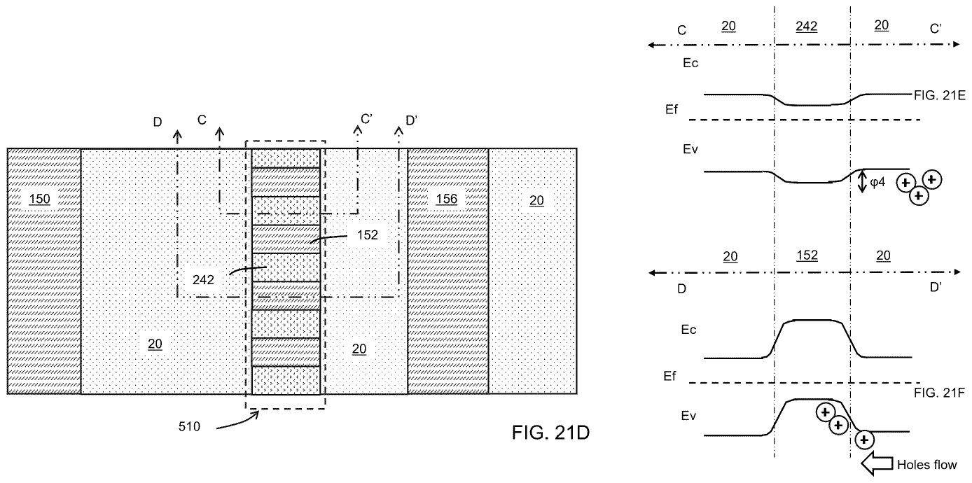

In embodiments in which PFET is processed, all process flows of 7000 are similarly applied but with different doping polarity as shown in a transistor-diode structure 2075 in FIG. 21A. In an instance in which components of NFET may be designed to have P-well 30, N+ gate electrode 220, N+ source 246, N+ drain 240, and N+/P+ diode, PFET may have N-well 20, P+ gate electrode 130, P+ source 156, P+ drain 150, and P+/N+ diode, respectively. For example, step 3010 in process flow 7000 may have phosphorous (P) implantation to substrate 40, forming N-well 20. All other components of polarity may be converted by changing ion plantation species from arsenic (As) or phosphorous (P) to boron (B) or boron fluoride (BF₂). For brevity, similar components and method steps that have been discussed above with respect to NFET may have a shortened or omitted description for PFET.

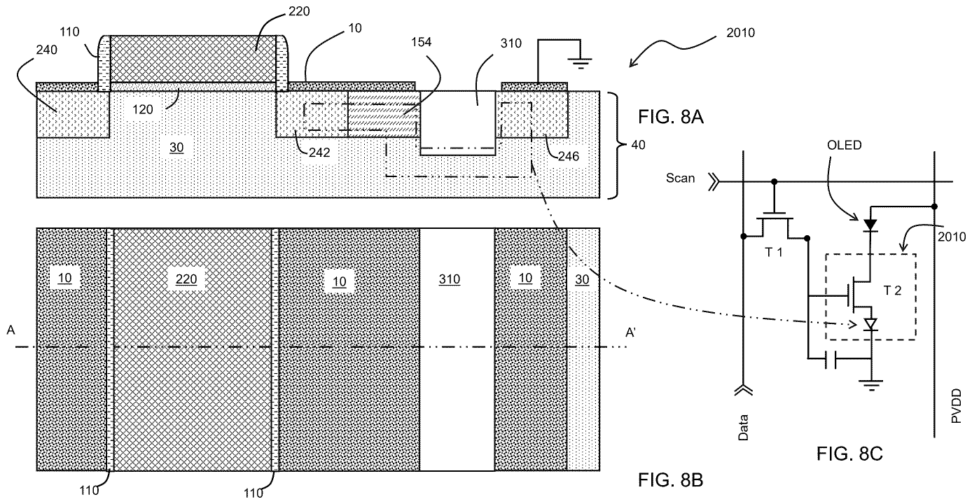

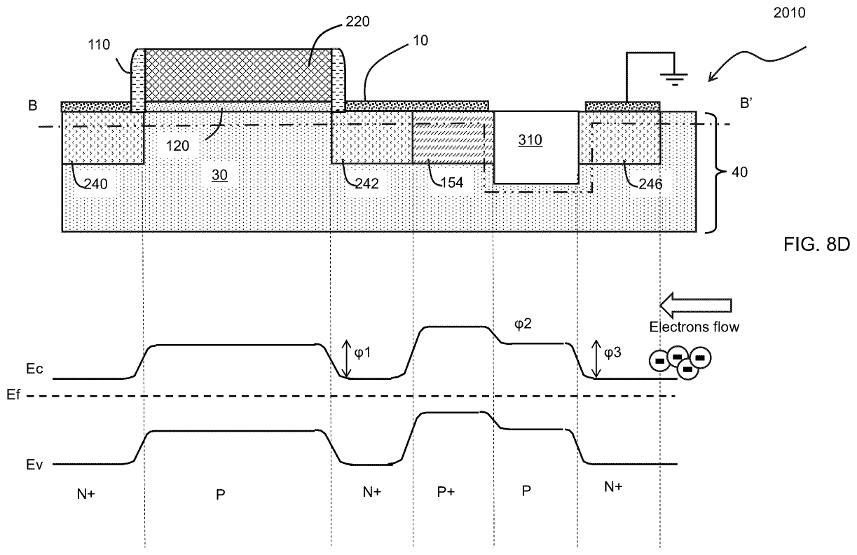

FIG. 8A illustrates a vertical cross-sectional view across cut line AA′ in FIG. 8B of a transistor-diode structure 2010. In FIG. 8A, referring to the process flow 5000, a N+ gate 220 may be positioned over a P-well 30 channel region, controlling a current flow between a source 246 and a drain 240. The source and drain may be N+ doped regions formed in the P-well 30. Adjacent to N+ region 242 is the P+ region 154 that shares a silicide contact with N+ region 242, where the shared contact is floated. Shallow trench isolation (STI) 310 as shown in a transistor-diode structure 2015 may be used to isolate P+ region 154 from N+ region 246, while STI 310 defines a part of P-well 30 as a diode structure simultaneously, such that electrons from source 246, when gate electrode 220 is biased (1V˜2V) to open, move sequentially through P-well 30 and region 510, surmounting energy barrier heights, resulting in gradual switching and high sub-threshold swing. In an instance in which 6V of PVDD is used, wherein power supply is operated in the range of 2V to 6V, the width of STI 310 may be wider than 0.5 um to prevent junction breakdown.

FIG. 8B shows a top view of FIG. 8A, illustrating the layout of the components within the pixel driver circuit. This view helps in understanding the spatial arrangement of a transistor-diode 2010, comprising silicide 10, N+ gate 220, spacer 110, STI 310, well 30, and the integration of different elements in the circuit.

FIG. 8C presents a schematic diagram of the pixel driver circuit. This circuit includes a switching transistor (T1), a pixel-driving transistor (T2) of a transistor-diode 2010, a light-emitting diode (LED), a scan line, a data line, and a power supply (PVDD). The pixel driver circuit may operate by controlling the current flowing through the LED to adjust brightness and gray-scale control. The operation principle may involve the interaction between the switching transistor (T1) and the pixel-driving transistor (T2) of a transistor-diode 2010. When the scan line activates T1, it allows T1's channel to be conductive. The data line may then provide the necessary voltage to the gate of the pixel-driving transistor (T2) through the conduction path of T1. The pixel-driving transistor (T2) of a transistor-diode 2010 may control the current flowing from power supply (PVDD) through the LED, thereby adjusting the brightness. The pixel-driving transistor (T2) is configured as an NMOSFET, where the gate is connected to the output of the switching transistor (T1). The source of the NMOSFET pixel-driving transistor (T2) is connected to the ground. The current flowing through the LED causes to emit light, and the brightness of the emitted light is proportional to the current controlled by T2 of a transistor-diode 2010.

FIG. 8D illustrates the energy band diagram across cutline BB′ of the NFET transistor-diode device 2010 when it is at equilibrium where no external bias is applied to the device, and the Fermi level (Ef) across the different regions is aligned. In an instance in which positive bias is applied to N+ gate 220, it may create an electric field that inverts the channel region of P-well 30, forming a conductive path between region 242 and region 240. Electrons may travel from N+ source region 246 through P-well 30 around STI 310, encountering the heavily doped P+ junction 154 as a driving transistor (T2) starts to open. Electrons may overcome potential barrier φ3 upon moving to P-well region 30 and then travel through potential barrier φ2, being smaller than φ3, as electrons move in P+ region 154. When N+ gate 220 is biased to open the channel, the channel resistance may drop by weak inversion, allowing electrons to enter the channel by lowering a surface potential φ1, and finally being collected at the N+ drain region 240. Depending on the gate bias conditions, a transistor operation may be in weak inversion, where sub-threshold operation dominates, or in strong inversion for peak current performance.

The inclusion of a diode structure 2010 in the carrier transport mechanism may affect the sub-threshold swing of T2 compared to a conventional transistor alone circuit. A more gradual transition from the off state to the on state, facilitated by the diode structure, may result in a higher sub-threshold swing value. This higher sub-threshold swing may benefit the LED pixel driver as it allows for advanced gray-scale control. By enabling a more controlled increase in current as the gate voltage rises, the diode structure may enhance the precision of the transistor's response to the gate voltage. This transistor-diode configuration enhances the sub-threshold swing, providing better control over the LED current and improving display uniformity and efficiency without larger area penalty, and enabling less process variation with device sub-threshold engineering. The present disclosure ensures that the process flows are compatible with a process of record (POR) without an additional mask and process knobs. This advanced control may be beneficial for achieving the fine gradations of brightness needed for accurate gray-scale representation in LED displays.

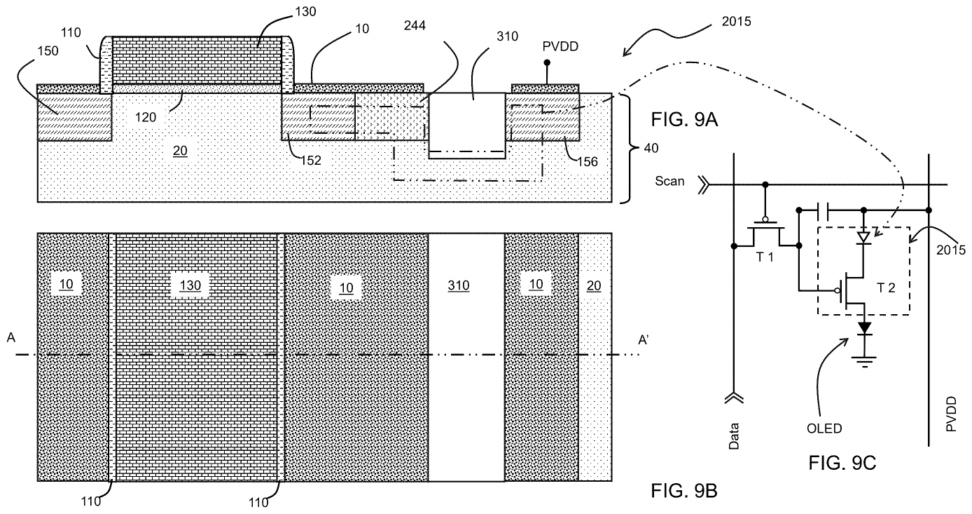

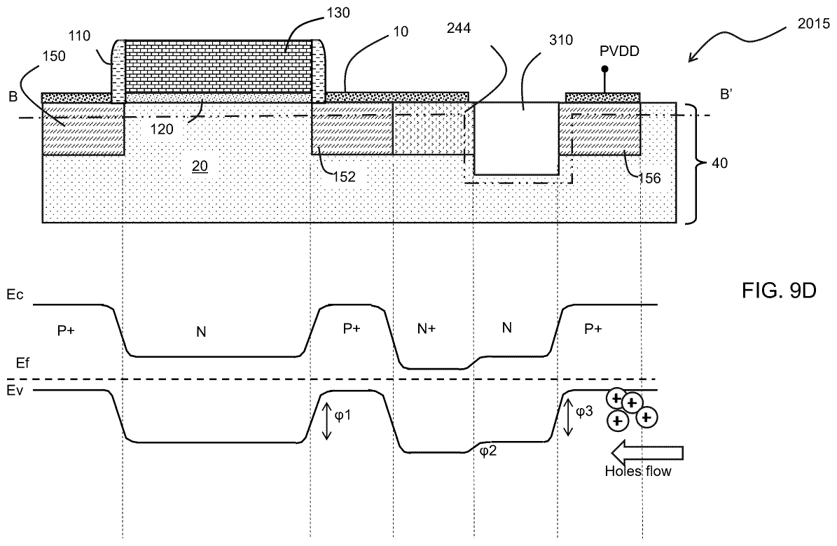

FIGS. 9A-9C illustrate a structure similar to FIG. 8 but with a PMOSFET configuration, featuring different polarities for a MOSFET, source/drain regions, well, and diode. For brevity, similar components and operation principles that have been discussed above with respect to FIGS. 1A, 2A and 8A may have a shortened description. The NMOSFET operation principles and physics described in FIGS. 1A, 2A, and 8A may be applied to PMOSFET similarly. Carrier transport mechanisms are similar to NMOSFET as described in FIGS. 1A and 8A.

FIG. 9A illustrates a vertical cross section view across cut line AA′ in FIG. 9B of a transistor-diode structure 2015. In FIG. 9A, referring to the process flow 5000, a gate 130 may control the current flow between P+ source 156 and P+ drain 150. The source and drain are P+ doped regions formed within the N-well 20. Adjacent to P+ region 152 is the N+ region 244 that shares a silicide contact with P+ region 152, where the shared contact is floated. Shallow trench isolation (STI) 310 as shown in a transistor-diode structure 2015 may be used to isolate N+ region 244 from P+ region 156, while STI 310 defines a part of N-well 20 as a diode structure simultaneously, such that holes from source 156, when gate electrode 130 is biased to open, experience gradual resistance changes through N-well 20 and N+ region 244, achieving high sub-threshold swing.

FIG. 9B shows a top view of FIG. 9A, illustrating the layout of the components within the pixel driver circuit. This view helps in understanding the spatial arrangement of silicide 10, gate 130, spacer 110, STI 310, N-well 20, and the integration of different elements in the circuit.

FIG. 9C presents a schematic diagram of the pixel driver circuit similar to FIG. 8C but with a PMOSFET configuration. FIG. 9C circuit includes a switching transistor (T1), a pixel-driving transistor (T2) of a transistor-diode structure 2015, a light-emitting diode (LED), a scan line, a data line, and a power supply (PVDD). The pixel driver circuit may operate by controlling the current flowing through the LED to adjust brightness and gray-scale control. The operation principle may involve the interaction between the switching transistor (T1) and the pixel-driving transistor (T2) of a transistor-diode structure 2015. When the scan line activates T1, it may allow T1's channel to be conductive. The data line then provides the necessary voltage to the gate of the pixel-driving transistor (T2) through the conduction path of T1. The pixel-driving transistor (T2) of a transistor-diode structure 2015 may control the current flowing from power supply (PVDD) through the LED, thereby adjusting the brightness. The pixel-driving transistor (T2) is configured as a PMOSFET, where the gate is connected to the output of the switching transistor (T1). The source of the PMOSFET pixel-driving transistor (T2) is connected to the power supply line (PVDD). The current flowing through the LED causes to emit light, and the brightness of the emitted light is proportional to the current controlled by T2 of a transistor-diode structure 2015. FIG. 9D illustrates the energy band diagram across cutline BB′ of the PFET transistor-diode device 2015 when it is at equilibrium where no external bias is applied to the device, and the Fermi level (Ef) across the different regions is aligned. In an instance in which negative bias is applied to P+ gate 130, it may create an electric field that accumulates the channel region of N-well 20, forming a conductive path between region 152 and region 150. Holes may travel from P+ source region 156 through N-well 20 around STI 310, encountering the heavily doped N+ junction 244 as a driving transistor (T2) starts to open. Holes may overcome potential barrier φ3 upon moving to N-well region 20 and then travel through potential barrier φ2, being smaller than φ3, as holes move in N+ region 244. When P+ gate 130 is biased to open the channel, the channel resistance may drop by weak accumulation, allowing holes to enter the channel by lowering a surface potential φ1, and finally being collected at the P+ drain region 150. Depending on the gate bias conditions, a transistor operation may be in weak accumulation, where sub-threshold operation dominates, or in strong accumulation for peak current performance.

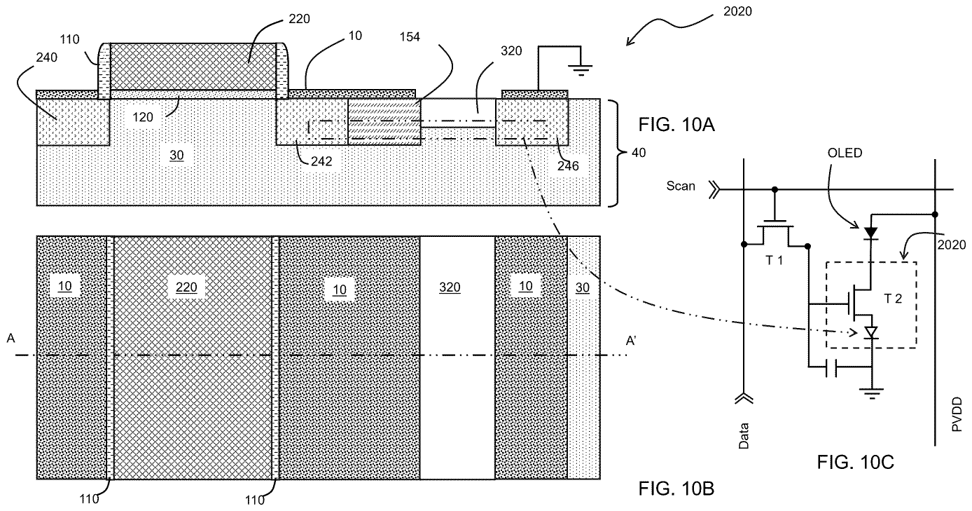

FIGS. 10A-10C illustrate a structure similar to FIG. 8A but with a shadow STI 320 configuration which has a shallower design than STI 310. For brevity, similar components and operation principles that have been discussed above with respect to FIGS. 1A and 8A may have a shortened description.

FIG. 10A illustrates a vertical cross-sectional view across cut line AA′ in FIG. 10B of a transistor-diode structure 2020. In FIG. 10A, referring to the process flow 5000, a N+ gate 220 may be positioned over a P-well 30 channel region, controlling a current flow between a source 246 and a drain 240. The source and drain may be N+ doped regions embedded in the P-well 30. Adjacent to N+ region 242 is the P+ region 154 that shares a silicide contact with N+ region 242, where the shared contact is floated. Shadow shallow trench isolation (sSTI) 320 may be used to isolate P+ region 154 from N+ region 246, while sSTI 320 defines a part of P-well 30 as a diode structure simultaneously, such that electrons from source 246, when gate electrode 220 is biased (1V˜2V) to open, move sequentially through P-well 30 and region 510, surmounting energy barrier heights, resulting in gradual switching and high sub-threshold swing. As compared to STI 310, sSTI 320 may be shallower than STI 310, offering a shortcut for the current path, where various device designs may be used. In an instance in which 6V of PVDD is used, wherein power supply is operated in the range of 2V to 6V, the width of sSTI 320 may be wider than 0.5 um to prevent junction breakdown.

FIG. 10B shows a top view of FIG. 10A, illustrating the layout of the components within the pixel driver circuit. This view helps in understanding the spatial arrangement of silicide 10, N+ gate 220, spacer 110, sSTI 320, P-well 30, and the integration of different elements in the circuit.

FIG. 10C presents a schematic diagram of the pixel driver circuit. This circuit includes a switching transistor (T1), a pixel-driving transistor (T2), a light-emitting diode (LED), a scan line, a data line, and a power supply (PVDD). The pixel driver circuit may operate by controlling the current flowing through the LED to adjust brightness and gray-scale control. The operation principle may involve the interaction between the switching transistor (T1) and the pixel-driving transistor (T2). When the scan line activates T1, it allows T1's channel to be conductive. The data line may then provide the necessary voltage to the gate of the pixel-driving transistor (T2) through the conduction path of T1. The pixel-driving transistor (T2) of a transistor-diode structure 2020 may control the current flowing from power supply (PVDD) through the LED, thereby adjusting the brightness. The pixel-driving transistor (T2) is configured as an NMOSFET, where the gate is connected to the output of the switching transistor (T1). The source of the NMOSFET pixel-driving transistor (T2) is connected to the ground. The current flowing through the LED causes to emit light, and the brightness of the emitted light is proportional to the current controlled by T2 of a transistor-diode structure 2020.

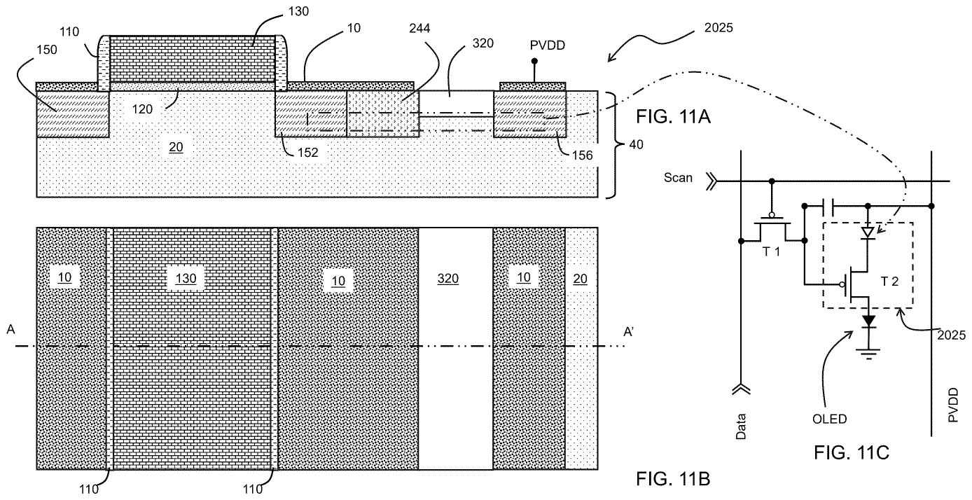

FIGS. 11A-11C illustrate another embodiment with a structure similar to the embodiment in FIG. 10A but with a PMOSFET configuration, featuring different polarities for a MOSFET, source/drain regions, well, and diode. For brevity, similar components and operation principles that have been discussed above with respect to FIGS. 1A, 2A, 9A, and 10A may have a shortened description. The NMOSFET operation principles and physics described in FIGS. 1A, 8A and 10A may be applied to PMOSFET similarly. Carrier transport mechanisms are similar to NMOSFET as described in FIGS. 1A, 8A, and 10A.

FIG. 11A illustrates a vertical cross-sectional view across cut line AA′ in FIG. 11B of a transistor-diode structure 2025. In FIG. 11A, referring to the process flow 5000, a gate 130 may control the current flow between P+ source 156 and drain P+150. The source and drain are P+ doped regions formed within the N-well 20. Adjacent to P+ region 152 is the N+ region 244 that shares a silicide contact with P+ region 152, where the shared contact is floated. Shadow shallow trench isolation (sSTI) 320 may be used to isolate N+ region 244 from P+ region 156, while sSTI 320 defines a part of N-well 20 as a diode structure simultaneously, such that holes from source 156, when gate electrode 130 is biased to open, experience gradual resistance changes through N-well 20 and N+ region 244, achieving high sub-threshold swing.

FIG. 11B shows a top view of FIG. 11A, illustrating the layout of the components within the pixel driver circuit. This view helps in understanding the spatial arrangement of silicide 10, gate 130, spacer 110, sSTI 320, N-well 20, and the integration of different elements in the circuit.

FIG. 11C presents a schematic diagram of the pixel driver circuit similar to FIG. 10C but with a PMOSFET configuration. FIG. 11C circuit includes a switching transistor (T1), a pixel-driving transistor (T2) of a transistor-diode structure 2025, a light-emitting diode (LED), a scan line, a data line, and a power supply (PVDD). As described in FIG. 9C, the pixel driver circuit may operate by controlling the current flowing through the LED to adjust brightness and gray-scale control.

FIGS. 12A-12C illustrate a transistor-diode structure 2030 with a N+ dummy gate 222 configuration. For brevity, similar components and operation principles that have been discussed above with respect to FIGS. 1A and 8A may have a shortened description.

In FIG. 12A, referring to the process flow 6000A, a N+ gate 220 may be positioned over a P-well 30 channel region, controlling a current flow between a source 246 and a drain 240, where a dummy gate 222 is formed simultaneously. A source and a drain may be N+ doped regions embedded in the P-well 30. Adjacent to N+ region 242 is the P+ region 154 that shares a silicide contact with N+ region 242, where the shared contact is floated. A N+ dummy gate 222 may be used to isolate P+ region 154 from N+ region 246, while a dummy gate 222 is floated and defines a part of P-well 30 as a diode structure simultaneously, such that electrons from source 246, when gate electrode 220 is biased (1V˜2V) to open, move sequentially through P-well 30 and region 510, surmounting energy barrier heights, resulting in gradual switching and high sub-threshold swing. In an instance in which 6V of PVDD is used, wherein power supply is operated in the range of 2V to 6V, the width of N+ dummy gate 222 may be wider than 0.5 um to prevent junction breakdown.

FIG. 12B shows a top view of FIG. 12A, illustrating the layout of the components within the pixel driver circuit. This view helps in understanding the spatial arrangement of silicide 10, N+ gate 220, spacer 110, N+ dummy gate 222, well 30, and the integration of different elements in the circuit.

FIG. 12C presents a schematic diagram of the pixel driver circuit with dummy gate 222. FIG. 12C circuit includes a switching transistor (T1), a pixel-driving transistor (T2) of a transistor-diode structure 2030, a light-emitting diode (LED), a scan line, a data line, and a power supply (PVDD). As described in FIG. 8C, the pixel driver circuit may operate by controlling the current flowing through the LED to adjust brightness and gray-scale control.

FIGS. 13A-13C illustrate a transistor-diode structure 2035 similar to FIGS. 12A-12C, but with a PMOSFET configuration. For brevity, similar components and operation principles that have been discussed above with respect to FIGS. 1A, 8A, 9A and 12A may have a shortened description.

FIG. 13A illustrates a vertical cross-sectional view across cut line AA′ in FIG. 13B of a transistor-diode structure 2035. In FIG. 13A, referring to process flow 6000A, gate 130 may control the current flow between P+ source 156 and P+ drain 150. The source and drain are P+ doped regions formed within the N-well 20. Adjacent to P+ region 152 is the N+ region 244 that shares a silicide contact with P+ region 152, where the shared contact is floated. A P+ dummy gate 132 may be used to isolate N+ region 244 from P+ region 156, while a dummy gate 132 is floated and defines a part of N-well 20 as a diode structure simultaneously, such that holes from source 156, when gate electrode 130 is biased to open, experience gradual resistance changes through N-well 20 and N+ region 244, achieving high sub-threshold swing.

FIG. 13B shows a top view of FIG. 13A, illustrating the layout of the components within the pixel driver circuit. This view helps in understanding the spatial arrangement of silicide 10, P+ gate 130, spacer 110, dummy P+ gate 132, N-well 20, and the integration of different elements in the circuit.

FIG. 13C presents a schematic diagram of the pixel driver circuit similar to FIG. 12C but with a PMOSFET configuration. FIG. 13C circuit includes a switching transistor (T1), a pixel-driving transistor (T2) of a transistor-diode structure 2035, a light-emitting diode (LED), a scan line, a data line, and a power supply (PVDD). As described in FIGS. 9C and 11C, the pixel driver circuit may operate by controlling the current flowing through the LED to adjust brightness and gray-scale control.

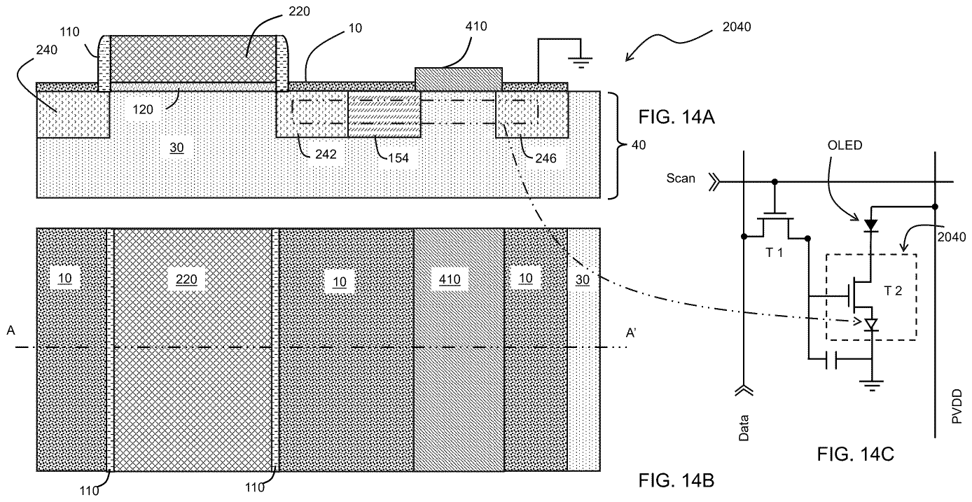

FIGS. 14A-14C illustrates a transistor-diode structure 2040 similar to FIGS. 12A-12C, but with a resist protection oxide (RPO) 410 configuration. For brevity, similar components and operation principles that have been discussed above with respect to FIGS. 1A, 8A, and 12A may have a shortened description.

FIG. 14A illustrates a vertical cross-sectional view across cut line AA′ in FIG. 14B of a transistor-diode structure 2040. In FIG. 14A, referring to process flow 3000, a N+ gate 220 may be positioned over a P-well 30 channel region, controlling a current flow between a source 246 and a drain 240. A source and a drain may be N+ doped regions embedded in the P-well 30. Adjacent to N+ region 242 is the P+ region 154 that shares a silicide contact with N+ region 242, where the shared contact is floated. A resist protection oxide (RPO) 410 may be used to isolate P+ region 154 from N+ region 246, while an RPO 410 defines a part of P-well 30 as a diode structure simultaneously, as shown in FIG. 3L. RPO 410 may be placed over P-well 30, such that the length of RPO 410 is large enough to cover P-well 30 between a P+ region 154 and a N+ source region 246 without silicide encroachment into P-well from P+ region 154 and N+ source 246, and such that electrons from source 246, when gate electrode 220 is biased (1V˜2V) to open, move sequentially through P-well 30 and region 510, surmounting energy barrier heights, resulting in gradual switching and high sub-threshold swing. In an instance in which 6V of PVDD is used, wherein power supply is operated in the range of 2V to 6V, the width of RPO 410 may be wider than 0.5 um to prevent junction breakdown.

FIG. 14B shows a top view of FIG. 14A, illustrating the layout of the components within the pixel driver circuit. This view helps in understanding the spatial arrangement of silicide 10, N+ gate 220, spacer 110, RPO 410, P-well 30, and the integration of different elements in the circuit.

FIG. 14C presents a schematic diagram of the pixel driver circuit similar to FIG. 12C but with a resist protection oxide (RPO) 410. FIG. 14C circuit includes a switching transistor (T1), a pixel-driving transistor (T2) of a transistor-diode structure 2040, a light-emitting diode (LED), a scan line, a data line, and a power supply (PVDD). As described in FIG. 8, the pixel driver circuit may operate by controlling the current flowing through the LED to adjust brightness and gray-scale control.

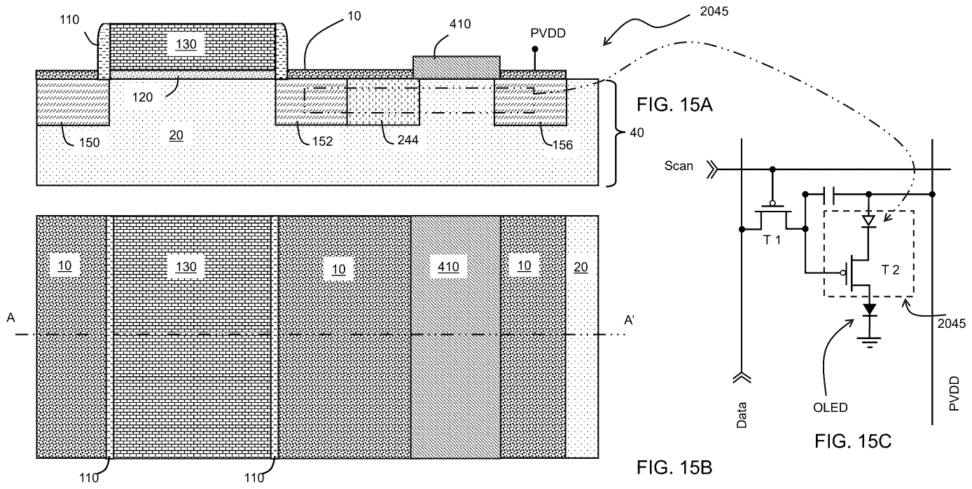

FIGS. 15A-15C illustrate a transistor-diode structure 2045 similar to FIGS. 14A-14C, but with a PMOSFET configuration. For brevity, similar components and operation principles that have been discussed above with respect to FIGS. 1A, 8A, and 9A may have a shortened description.

FIG. 15A illustrates a vertical cross-sectional view across cut line AA′ in FIG. 15B of a transistor-diode structure 2045. In FIG. 15A, referring to the process flow 3000, gate 130 may control the current flow between P+ source 156 and drain P+ 150. The source and drain are P+ doped regions embedded in the N-well 20. Adjacent to P+ region 152 is the N+ region 244 that shares a silicide contact with P+ region 152, where the shared contact is floated. A resist protection oxide (RPO) 410 may be used to isolate N+ region 244 from P+ region 156, while a resist protection oxide (RPO) 410 defines a part of N-well 20 as a diode structure simultaneously, as shown in FIG. 3L. RPO 410 may be placed on N-well 20, such that the length of RPO is large enough to cover N-well 20 between a N+ region 244 and a P+ source region 156 without silicide encroachment into N-well 20 from N+ region 244 and P+ source 156, such that holes from source 156, when P+ gate electrode 130 is biased to open, experience gradual resistance changes through N-well 20 and N+ region 244, achieving high sub-threshold swing.

FIG. 15B shows a top view of FIG. 15A, illustrating the layout of the components within the pixel driver circuit. This view helps in understanding the spatial arrangement of silicide 10, P+ gate 130, spacer 110, resist protection oxide (RPO) 410, N-well 20, and the integration of different elements in the circuit.

FIG. 15C presents a schematic diagram of the pixel driver circuit similar to FIG. 14C but with a PMOSFET configuration. FIG. 15C circuit includes a switching transistor (T1), a pixel-driving transistor (T2) of a transistor-diode structure 2045, a light-emitting diode (LED), a scan line, a data line, and a power supply (PVDD). As described in FIG. 9C, the pixel driver circuit may operate by controlling the current flowing through the LED to adjust brightness and gray-scale control.

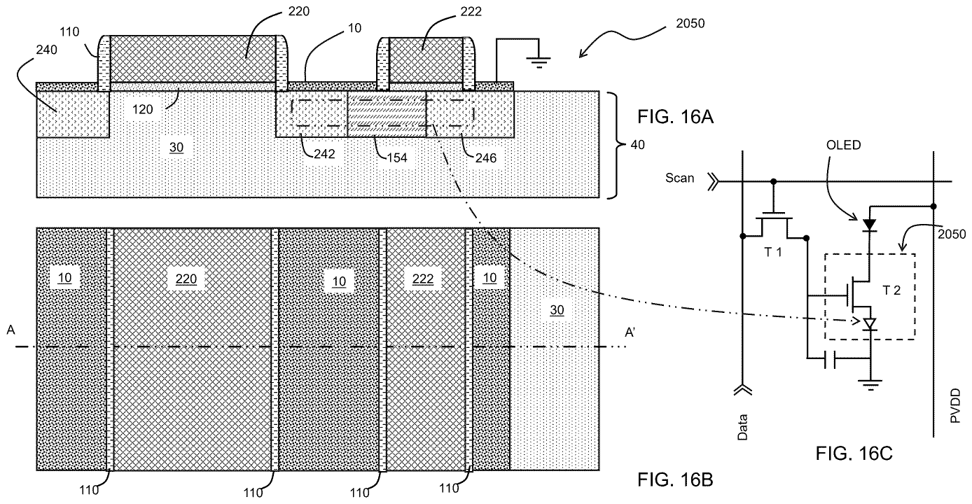

FIGS. 16A-16C illustrates a transistor-diode structure 2050 with a N+ dummy gate 222 as a mask structure configured to form separate metallic contact on N+ source region 246 while protecting junctions between P+ region 154 and N+ source region 246. For brevity, similar components and operation principles that have been discussed above with respect to FIGS. 1A and 8A may have a shortened description.

FIG. 16A illustrates a vertical cross-sectional view across cut line AA′ in FIG. 16B of a transistor-diode structure 2050. In FIG. 16A, referring to the process flow 6000B, a N+ gate 220 may be positioned over a P-well 30 channel region, controlling a current flow between a source 246 and a drain 240. A source and a drain may be N+ doped regions formed within the P-well 30. Adjacent to N+ region 242 is the P+ region 154 that shares a silicide contact with N+ region 242, where the shared contact is floated. A N+ dummy gate 222 may be floated and configured to form separate metallic contact on N+ source region 246 while protecting junctions between P+ region 154 and N+ source region 246 simultaneously, as shown in FIG. 6N, such that electrons from source 246, when gate electrode 220 is biased (1V˜2V) to open, experience gradual resistance changes through P+ region 154, achieving high sub-threshold swing.

FIG. 16B shows a top view of FIG. 16A, illustrating the layout of the components within the pixel driver circuit. This view helps in understanding the spatial arrangement of silicide 10, N+ gate 220, spacer 110, dummy N+ gate 222, P-well 30, and the integration of different elements in the circuit.

FIG. 16C presents a schematic diagram of the pixel driver circuit with a dummy N+ gate 222 configured to form a separate metallic contact on the N+ source region 246. FIG. 16C circuit includes a switching transistor (T1), a pixel-driving transistor (T2) of a transistor-diode 2050, a light-emitting diode (LED), a scan line, a data line, and a power supply (PVDD). As described in FIG. 8C, the pixel driver circuit may operate by controlling the current flowing through the LED to adjust brightness and gray-scale control.

FIGS. 17A-17C illustrates a transistor-diode structure 2055 with a P+ dummy gate 132 as a mask structure configured to form separate metallic contact on P+ source region 156 while protecting junctions between N+ region 244 and P+ source region 156. For brevity, similar components and operation principles that have been discussed above with respect to FIGS. 1A, 8A, and 16A may have a shortened description.

FIG. 17A illustrates a vertical cross-sectional view across cut line AA′ in FIG. 17B of a transistor-diode structure 2055. In FIG. 17A, referring to the process flow 6000B, a P+ gate 130 may be positioned over an N-well 20 channel region, controlling a current flow between a source 156 and a drain 150. A source and a drain may be P+ doped regions formed within the N-well 20. Adjacent to P+ region 152 is the N+ region 244 that shares a silicide contact with P+ region 152, where the shared contact is floated. A P+ dummy gate 132 may be floated and configured to form separate metallic contact on P+ source region 156 while protecting junctions between N+ region 244 and P+ source region 156 simultaneously, as shown in FIG. 6N, such that holes from source 156, when P+ gate electrode 130 is biased to open, experience gradual resistance changes through N-well 20 and N+ region 244, achieving high sub-threshold swing.

FIG. 17B shows a top view of FIG. 17A, illustrating the layout of the components within the pixel driver circuit. This view helps in understanding the spatial arrangement of silicide 10, gate 130, spacer 110, dummy gate 132, N-well 20, and the integration of different elements in the circuit.

FIG. 17C presents a schematic diagram of the pixel driver circuit with a dummy gate 132 configured to form a separate metallic contact on the P+ source region 156. FIG. 17C circuit includes a switching transistor (T1), a pixel-driving transistor (T2), a light-emitting diode (LED), a scan line, a data line, and a power supply (PVDD). As described in FIG. 9C, the pixel driver circuit may operate by controlling the current flowing through the LED to adjust brightness and gray-scale control.

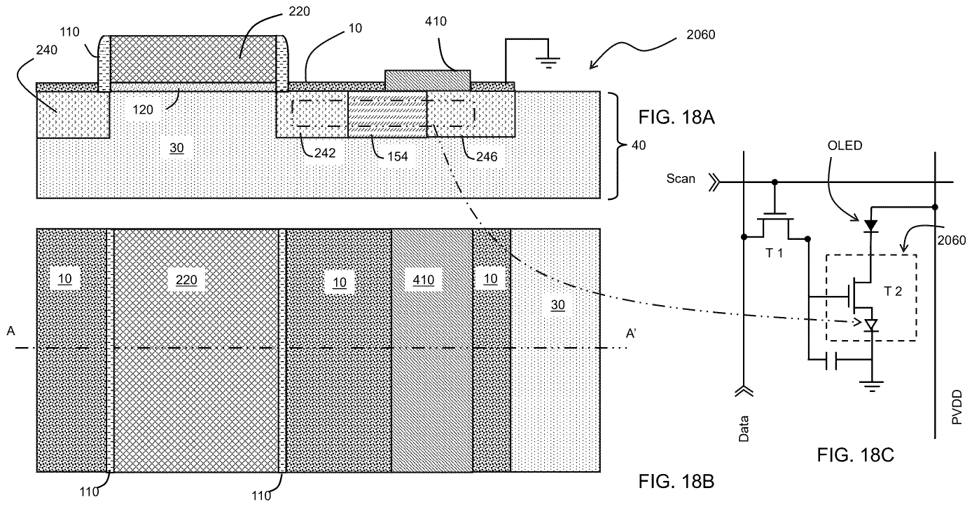

FIGS. 18A-18C illustrates a transistor-diode structure 2060 with a resist protection oxide (RPO) 410 as a mask structure configured to form separate metallic contact on N+ source region 246 while protecting junctions between P+ region 154 and N+ source region 246. For brevity, similar components and operation principles that have been discussed above with respect to FIGS. 1A and 8A may have a shortened description.

FIG. 18A illustrates a vertical cross-sectional view across cut line AA′ in FIG. 18B of a transistor-diode structure 2060. In FIG. 18A, referring to the process flow 3000, a N+ gate 220 may be positioned over a P-well 30 channel region, controlling a current flow between a source 246 and a drain 240. A source and a drain may be N+ doped regions formed within the P-well 30. Adjacent to N+ region 242 is the P+ region 154 that shares a silicide contact with N+ region 242, where the shared contact is floated. A resist protection oxide (RPO) 410 may be configured to form separate metallic contact on N+ source region 246 while protecting junctions between P+ region 154 and N+ source region 246 simultaneously, as shown in FIG. 3K, such that electrons from source 246, when gate electrode 220 is biased (1V˜2V) to open, experience gradual resistance changes through P+ region 154, achieving high sub-threshold swing.

FIG. 18B shows a top view of FIG. 18A, illustrating the layout of the components within the pixel driver circuit. This view helps in understanding the spatial arrangement of silicide 10, N+ gate 220, spacer 110, resist protection oxide (RPO), P-well 30, and the integration of different elements in the circuit.

FIG. 18C presents a schematic diagram of the pixel driver circuit with a resist protection oxide (RPO) configured to form a separate metallic contact on the N+ source region 246. FIG. 18C circuit includes a switching transistor (T1), a pixel-driving transistor (T2) of a transistor-diode structure 2060, a light-emitting diode (LED), a scan line, a data line, and a power supply (PVDD). As described in FIG. 8C, the pixel driver circuit may operate by controlling the current flowing through the LED to adjust brightness and gray-scale control.

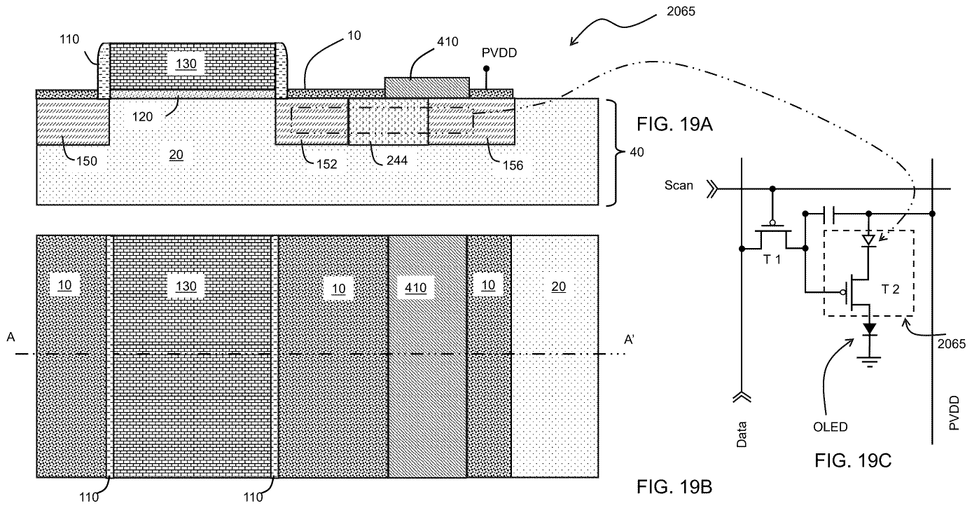

FIGS. 19A-19C illustrates a transistor-diode structure 2065 with a resist protection oxide (RPO) 410 as a mask structure configured to form separate metallic contact on P+ source region 156 while protecting junctions between N+ region 244 and P+ source region 156. For brevity, similar components and operation principles that have been discussed above with respect to FIGS. 1A, 8A, and 18A may have a shortened description.

FIG. 19A illustrates a vertical cross-sectional view across cut line AA′ in FIG. 19B of a transistor-diode structure 2065. In FIG. 19A, referring to the process flow 3000, P+ gate 130 may be positioned over a N-well 20 channel region, controlling a current flow between a source 156 and a drain 150. A source and a drain may be P+ doped regions formed within the N-well 20. Adjacent to P+ region 152 is the N+ region 244 that shares a silicide contact with P+ region 152, where the shared contact is floated. A resist protection oxide (RPO) 410 may be configured to form separate metallic contact on P+ source region 156 while protecting junctions between N+ region 244 and P+ source region 156 simultaneously, as shown in FIG. 3K, such that holes from source 156, when P+ gate electrode 130 is biased to open, experience gradual resistance changes through N+ region 244, achieving high sub-threshold swing.

FIG. 19B shows a top view of FIG. 19A, illustrating the layout of the components within the pixel driver circuit. This view helps in understanding the spatial arrangement of silicide 10, gate 130, spacer 110, resist protection oxide 410, N-well 20, and the integration of different elements in the circuit.

FIG. 19C presents a schematic diagram of the pixel driver circuit with a resist protection oxide 410 configured to form a separate metallic contact on the P+ source region 156. FIG. 19C circuit includes a switching transistor (T1), a pixel-driving transistor (T2) of a transistor-diode structure 2065, a light-emitting diode (LED), a scan line, a data line, and a power supply (PVDD). As described in FIG. 9C, the pixel driver circuit may operate by controlling the current flowing through the LED to adjust brightness and gray-scale control.

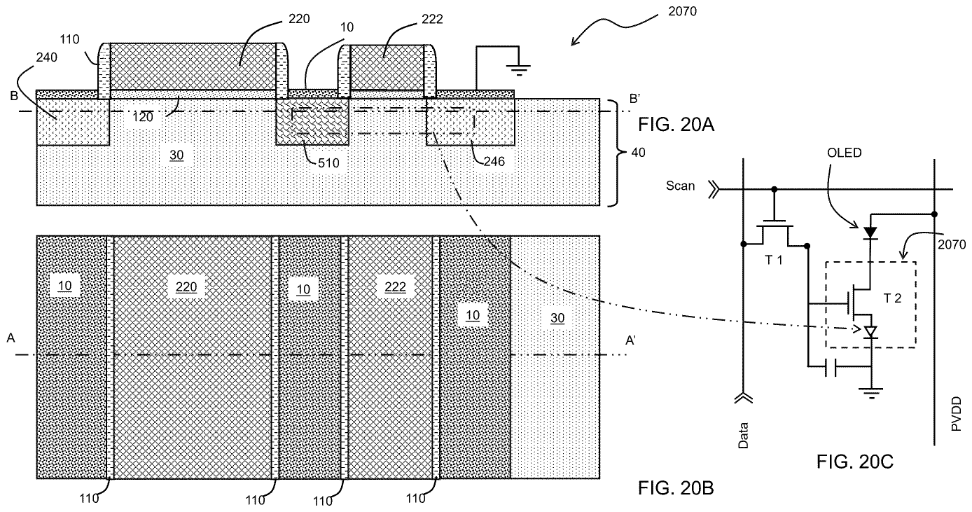

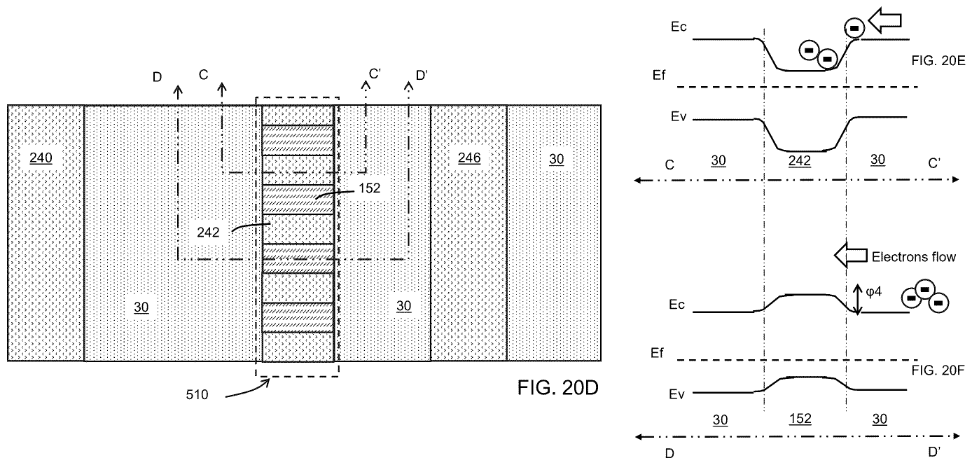

FIGS. 20A-20C illustrate a transistor-diode structure 2070 with a mixed cross-coupled arrangement of junction area 510 and a dummy gate 222 as a mask structure configured to form separate metallic contact on N+ source region 246 while using P-well 30 as a part of a diode structure. Similar to a transistor-diode structure 2030 shown in FIG. 12A, a transistor-diode structure 2070 has alternating N+ region 242 and P+ region 152 within mixed cross-coupled junction 510, in parallel to P-well 30, such that electrons from source 246, when gate electrode 220 is biased (1V˜2V) to open, experience gradual resistance changes through P-well 30 and P+ region 152 of a mixed cross-coupled junction 510, achieving high sub-threshold swing. For brevity, similar components and operation principles that have been discussed above with respect to FIGS. 1A and 8A may have a shortened description.

FIG. 20A illustrates a vertical cross-sectional view across cut line AA′ in FIG. 20B of a transistor-diode structure 2070. In FIG. 20A, referring to process flow 7000, a N+ gate 220 may be positioned over a P-well 30 channel region, controlling a current flow between a source 246 and a drain 240. A source and a drain may be N+ doped regions embedded in the P-well 30. A mixed cross-coupled arrangement junction 510 may comprise N+ region 242 and P+ region 152, which are placed in alternating order, as shown in FIGS. 7D and 7F. Adjacent to N+ region 242 is the P+ region 152, which shares a silicide contact with N+ region 242, where the shared contact is floated. A N+ dummy gate 222 may be floated and configured to form separate metallic contact on N+ source region 246 while using P-well 30 as a part of a diode structure. In an instance in which 6V of PVDD is used, wherein power supply is operated in the range of 2V to 6V, the width of a dummy gate 222 may be wider than 0.5 um to prevent junction breakdown.

FIG. 20B shows a top view of FIG. 20A, illustrating the layout of the components within the pixel driver circuit. This view helps in understanding the spatial arrangement of silicide 10, N+ gate 220, spacer 110, dummy N+ gate 222, P-well 30, and the integration of different elements in the circuit.

FIG. 20C presents a schematic diagram of the pixel driver circuit with a dummy N+ gate 222 configured to form a separate metallic contact on the N+ source region 246. FIG. 20C circuit includes a switching transistor (T1), a pixel-driving transistor (T2) of a transistor-diode structure 2070, a light-emitting diode (LED), a scan line, a data line, and a power supply (PVDD). As described in FIG. 8C, the pixel driver circuit may operate by controlling the current flowing through the LED to adjust brightness and gray-scale control.

FIG. 20D shows a horizontal cross-sectional view across cut line BB′ in FIG. 20A, illustrating the layout of the components within the pixel driver circuit. This view helps in understanding the spatial arrangement of drain 240, P-well 30, mixed cross-coupled arrangement 510 of junctions, N+ region 242, P+ region 152, N+ source 246, and the integration of different elements in the circuit.

FIGS. 20E and 20F illustrate the carrier transport mechanism facilitated by the mixed cross-coupled arrangement of junctions, which may contribute to a high sub-threshold swing. In FIG. 20E, the energy band diagram is shown along the cross-section C-C′ in FIG. 20D. In FIG. 20F, the energy band diagram is shown along the cross-section D-D′ in FIG. 20D. The flow of electrons from the N+ source region 246 through the P-well 30 towards the N+ region 242 in area 510 is facilitated by the low conduction band (Ec) at the N+ region 242, as described in FIG. 20E, which provides a path for electron flow. In contrast, the electrons flowing through P-well 30 towards the P+ region 152 in area 510 encounter a higher energy barrier (Φ4), making carrier transport more difficult, as described in FIG. 20F. A more gradual transition from the off state to the on state, facilitated by the diode structure, may result in a higher sub-threshold swing value. This higher sub-threshold swing may benefit the LED pixel driver as it allows for advanced gray-scale control.

FIGS. 21A-21F illustrate a transistor-diode structure 2075 similar to FIG. 20, but with a PMOSFET configuration. FIG. 21 shows a mixed cross-coupled arrangement of junctions 510 and a dummy gate 132 as a mask structure configured to form separate metallic contact on P+ source region 156 while using N-well 20 as a part of a diode structure. For brevity, similar components and operation principles that have been discussed above with respect to FIGS. 1A, 8A, 9A, and 20A may have a shortened description.

In FIG. 21A, referring to process flow 7000, a P+ gate 130 may be positioned over an N-well 20 channel region, controlling a current flow between a source 156 and a drain 150. A source and a drain may be P+ doped regions embedded in the N-well 20. A mixed cross-coupled arrangement junction 510 may comprise N+ region 242 and P+ region 152, which are placed in alternating order, as shown in FIGS. 7D and 7F. Adjacent to N+ region 242 is the P+ region 152, which shares a silicide contact with N+ region 242, where the shared contact is floated. A P+ dummy gate 132 may be floated and configured to form separate metallic contact on P+ source region 156 while using N-well 20 as a part of a diode structure. Similar to a transistor-diode structure 2035 shown in FIG. 13A, a transistor-diode structure 2075 has alternating N+ region 242 and P+ region 152 within mixed cross-coupled junction 510, in parallel to N-well 20, such that holes from source 156, when P+ gate electrode 130 is biased to open, experience gradual resistance changes through N-well 20 and N+ region 242 of a mixed cross-coupled junction 510, achieving high sub-threshold swing.

FIG. 21B shows a top view of FIG. 21A, illustrating the layout of the components within the pixel driver circuit. This view helps in understanding the spatial arrangement of silicide 10, P+ gate 130, spacer 110, dummy P+ gate 132, N-well 20, and the integration of different elements in the circuit.

FIG. 21C presents a schematic diagram of the pixel driver circuit with PMOSFET and P+ dummy gate 132 configured to form a separate metallic contact on the P+ source region 156. FIG. 21C circuit includes a switching transistor (T1), a pixel-driving transistor (T2) of a transistor-diode structure 2075, a light-emitting diode (LED), a scan line, a data line, and a power supply (PVDD). As described in FIG. 9C, the pixel driver circuit may operate by controlling the current flowing through the LED to adjust brightness and gray-scale control.

FIG. 21D shows a horizontal cross-sectional view across cut line BB′ in FIG. 21A, illustrating the layout of the components within the pixel driver circuit. This view helps in understanding the spatial arrangement of drain 150, N-well 20, mixed cross-coupled arrangement 510 of junctions, N+ region 242, P+ region 152, P+ source 156, and the integration of different elements in the circuit.

FIGS. 21E and 21F illustrate the carrier transport mechanism facilitated by the mixed cross-coupled arrangement of junctions, which may contribute to a high sub-threshold swing. In FIG. 21E, the energy band diagram is shown along the cross-section C-C′ in FIG. 21D. In FIG. 21F, the energy band diagram is shown along the cross-section D-D′ in FIG. 21D. The flow of holes from the P+ source region 156 through the N-well 20 towards the P+ region 152 in area 510 is facilitated by the low valence band (Ev) at the P+ region 152, as described in FIG. 21F, which provides a path for hole flow. In contrast, the holes flowing through N-well 20 towards the N+ region 242 in area 510 encounter a higher energy barrier (Φ4), making carrier transport more difficult, as described in FIG. 21E. A more gradual transition from the off state to the on state, facilitated by the diode structure, may result in a higher sub-threshold swing value. This higher sub-threshold swing may benefit the LED pixel driver as it allows for advanced gray-scale control.

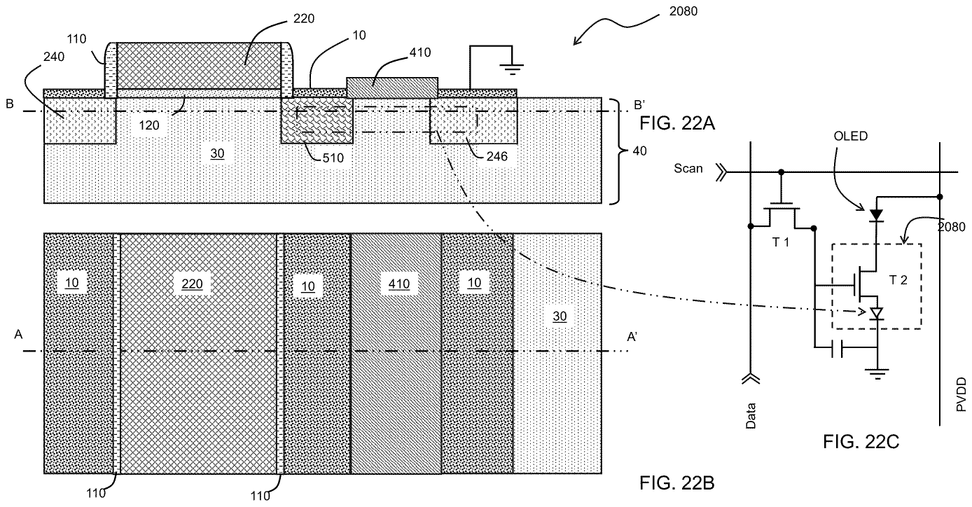

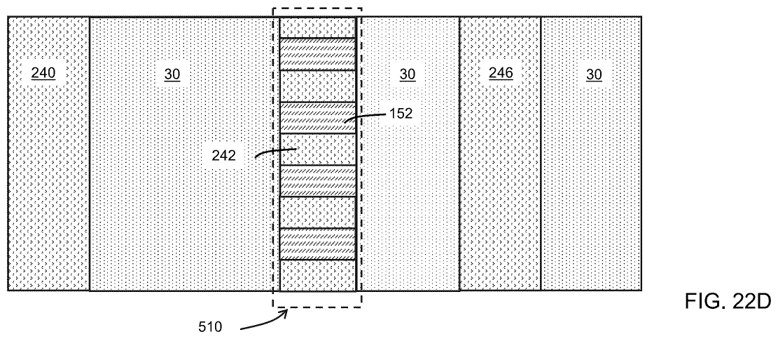

FIGS. 22A-22C illustrate a transistor-diode structure 2080 similar to FIG. 20, but with a resist protection oxide (RPO) 410 configuration. A transistor-diode structure 2080 includes a mixed cross-coupled arrangement of junctions 510 and a resist protection oxide (RPO) as a mask structure configured to form separate metallic contact on N+ source region 246 while using P-well 30 as a part of a diode structure. For brevity, similar components and operation principles that have been discussed above with respect to FIGS. 1A, 8A, and 20A may have a shortened description.

FIG. 22A illustrates a vertical cross-sectional view across cut line AA′ in FIG. 22B of a transistor-diode structure 2080. In FIG. 22A, referring to process flow 4000, a N+ gate 220 may be positioned over a P-well 30 channel region, controlling a current flow between a source 246 and a drain 240. A source and a drain may be N+doped regions embedded in the P-well 30. A mixed cross-coupled arrangement junction 510 may comprise N+ region 242 and P+ region 152, which are placed in alternating order, as shown in FIGS. 4D and 4F. Adjacent to N+ region 242 is the P+ region 152, which shares a silicide contact with N+ region 242, where the shared contact is floated. A resist protection oxide (RPO) 410 may be configured to form separate metallic contact on N+ source region 246 while using P-well 30 as a part of a diode structure. RPO 410 may be placed on P-well 30, such that the length of RPO is large enough to cover P-well 30 between a mixed cross-coupled arrangement region 510 and a N+ source region 246, and such that electrons from source 246, when gate electrode 220 is biased (1V˜2V) to open, experience gradual resistance changes through P-well 30 and P+ region 152 of a mixed cross-coupled junction 510, achieving high sub-threshold swing. In an instance in which 6V of PVDD is used, wherein power supply is operated in the range of 2V to 6V, the width of RPO 410 may be wider than 0.5 um to prevent junction breakdown. For brevity, similar components and operation principles that have been discussed above with respect to FIGS. 1A and 8A may have a shortened description.

FIG. 22B shows a top view of FIG. 22A, illustrating the layout of the components within the pixel driver circuit. This view helps in understanding the spatial arrangement of silicide 10, N+ gate 220, spacer 110, resist protection oxide (RPO) 410, P-well 30, and the integration of different elements in the circuit.

FIG. 22C presents a schematic diagram of the pixel driver circuit with a resist protection oxide (RPO) 410 configured to form a separate metallic contact on the N+ source region 246. FIG. 22C circuit includes a switching transistor (T1), a pixel-driving transistor (T2) of a transistor-diode structure 2080, a light-emitting diode (LED), a scan line, a data line, and a power supply (PVDD). As described in FIG. 8, the pixel driver circuit may operate by controlling the current flowing through the LED to adjust brightness and gray-scale control.

FIG. 22D shows a horizontal cross-sectional view across cut line BB′ in FIG. 22A of a transistor-diode structure 2080, illustrating the layout of the components within the pixel driver circuit. This view helps in understanding the spatial arrangement of drain 240, P-well 30, mixed cross-coupled arrangement 510 of junctions, N+ region 242, P+ region 152, N+ source 246, and the integration of different elements in the circuit.

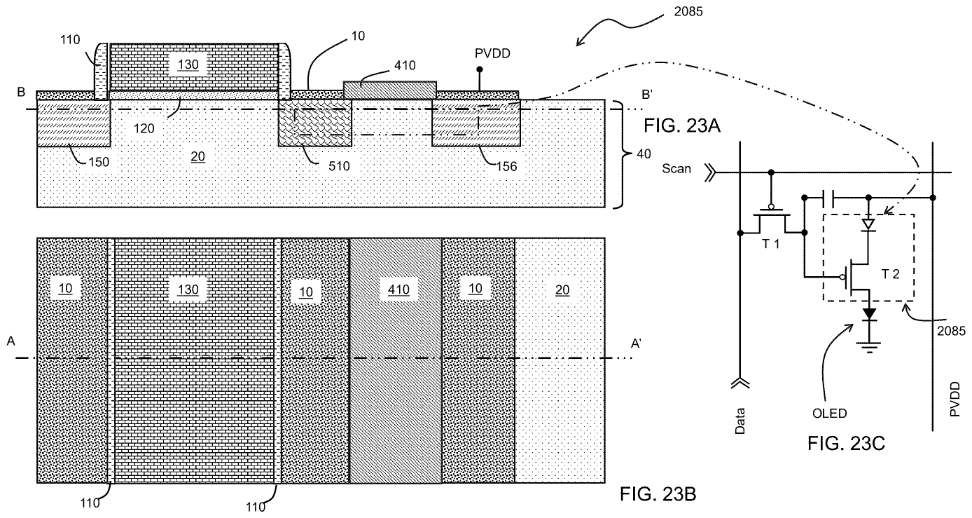

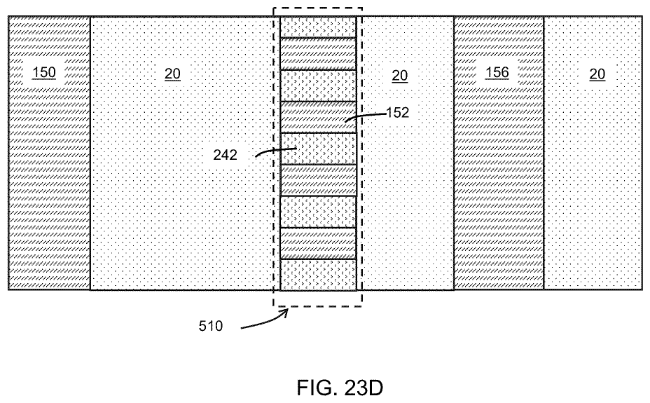

FIGS. 23A-23C illustrate a transistor-diode structure 2085 similar to FIG. 22A-22C, but with a PMOSFET configuration. A transistor-diode structure 2085 includes a mixed cross-coupled arrangement of junctions 510 and a resist protection oxide (RPO) as a mask structure configured to form separate metallic contact on P+ source region 156 while using N-well 20 as a part of a diode structure. For brevity, similar components and operation principles that have been discussed above with respect to FIGS. 1A, 8A, 9A, 20A, and 22A may have a shortened description.

In FIG. 23A, referring to process flow 4000, a P+ gate 130 may be positioned over an N-well 20 channel region, controlling a current flow between a source 156 and a drain 150. A source and a drain may be P+ doped regions embedded in the N-well 20. A mixed cross-coupled arrangement junction 510 may comprise N+ region 242 and P+ region 152, which are placed in alternating order, as shown in FIGS. 4D and 4F. Adjacent to N+ region 242 is the P+ region 152, which shares a silicide contact with N+ region 242, where the shared contact is floated. A resist protection oxide (RPO) may be configured to form separate metallic contact on P+ source region 156 while using N-well 20 as a part of a diode structure. RPO 410 may be placed on N-well 20, such that the length of RPO is large enough to cover N-well 20 between a mixed cross-coupled arrangement region 510 and a P+ source region 156, and, such that holes from source 156, when P+ gate electrode 130 is biased to open, experience gradual resistance changes through N-well 20 and N+ region 242 of a mixed cross-coupled junction 510, achieving high sub-threshold swing.

FIG. 23B shows a top view of FIG. 23A, illustrating the layout of the components within the pixel driver circuit. This view helps in understanding the spatial arrangement of silicide 10, P+ gate 130, spacer 110, resist protection oxide (RPO) 410, N-well 20, and the integration of different elements in the circuit.

FIG. 23C presents a schematic diagram of the pixel driver circuit with a resist protection oxide (RPO) 410 configured to form a separate metallic contact on the P+ source region 156. FIG. 23C circuit includes a switching transistor (T1), a pixel-driving transistor (T2), a light-emitting diode (LED), a scan line, a data line, and a power supply (PVDD). As described in FIG. 9C, the pixel driver circuit may operate by controlling the current flowing through the LED to adjust brightness and gray-scale control.

FIG. 23D shows a top view across cut line BB′ in FIG. 23A, illustrating the layout of the components within the pixel driver circuit. This view helps in understanding the spatial arrangement of drain 150, N-well 20, mixed cross-coupled arrangement 510 of junctions, N+ region 242, P+ region 152, P+ source 156, and the integration of different elements in the circuit.

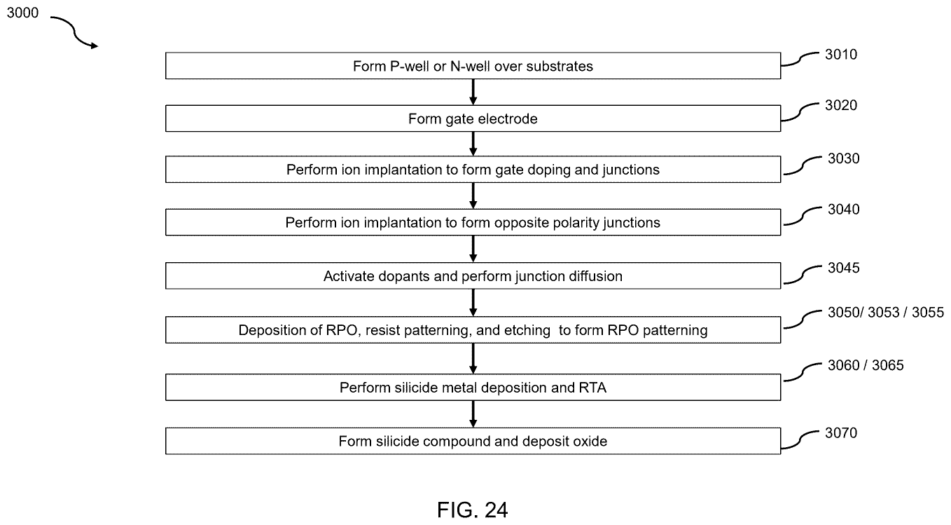

FIG. 24 is a process flowchart that illustrates the method steps to form a pixel driver transistor with a diode structure using RPO. With reference to FIGS. 14A, 15A, 18A, 19A and 24, method 3000 is illustrated. In step 3010, a P-well 30 or N-well 20 may be formed over substrate 40. This step involves initial cleaning and surface treatment, followed by doping processes to create P-well or N-well regions using techniques such as ion implantation and diffusion. In step 3020, a gate oxide or gate dielectric 120 may be deposited and patterned. An undoped gate electrode 100 may be formed over the gate oxide 120. The undoped gate electrode 100 may be made of polycrystalline silicon or metal, such as TiN, TaN, and W, patterned using photolithography and etched to form the gate structure. Spacers 110 may be deposited and formed around the gate structure. Step 3030 involves performing ion implantation to form the gate electrode doping and source/drain junctions simultaneously, where dopant ions such as phosphorus or arsenic for NMOSFET or boron for PMOSFET are introduced into substrate 40. Following implantation, an annealing process may be conducted for dopant activation. Following step 3030, in the case of NFET having a P-well 30, N+ gate electrode 220, N+ source 246, N+ drain 240, and N+/P+ diode may be formed. In the case of a PFET having a N-well 20, P+ gate electrode 130, P+ source 156, P+ drain 150, and P+/N+ diode may be formed. In step 3040, ion implantation may be performed to form an opposite polarity junction. In some embodiments, boron may be introduced to form the P+ region 154 for NMOSFET. In other embodiments, phosphorous or arsenic may be introduced to form the N+ region 244 for PMOSFET. Step 3045, which is common to all process flows, may involve annealing for dopant activation and junction diffusion, ensuring that the dopants occupy proper lattice positions. In steps 3050 to 3055, the resist protection oxide (RPO) 410 may be deposited and patterned using photolithography to define areas for subsequent silicidation. In step 3060, silicide metal 9 may be deposited over the source and drain regions using sputtering or evaporation techniques. Rapid thermal anneal (RTA) may be performed to form metal silicide in step 3065, followed by selective etching to remove unreacted metal, and deposition of a thick oxide layer for further integration in step 3070. Various embodiments allow for versatile configurations that may be adapted to different display requirements and manufacturing processes without an additional mask and process steps, where the process flows described herein are compatible with a process of records (POR), enabling less process variation and no larger area penalty. This flexibility ensures that the pixel driver designs can be tailored to meet specific performance and integration needs, making them suitable for a wide range of LED display applications.

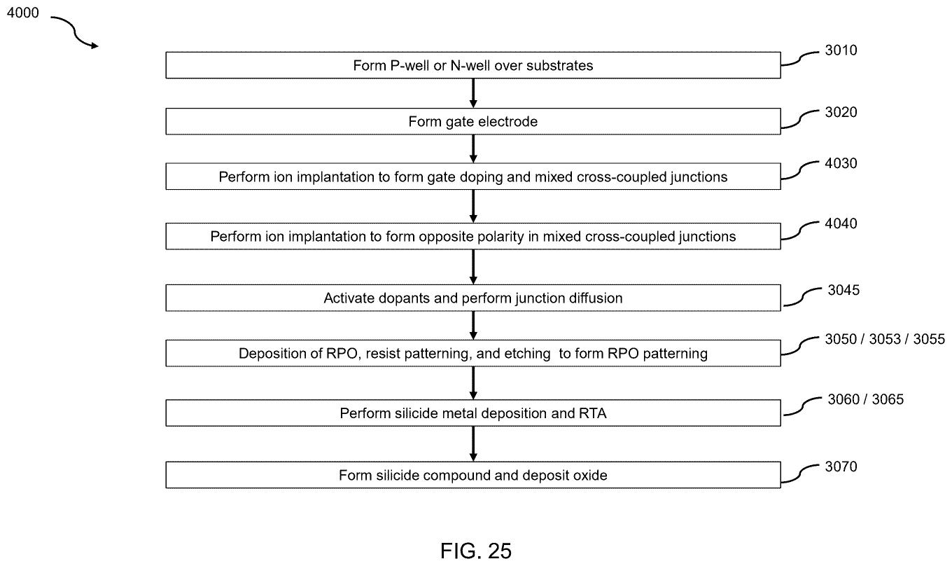

FIG. 25 is a process flowchart that illustrates the method steps to form a pixel driver transistor with mixed cross-coupled diode structures using RPO. With reference to FIGS. 22A, 23A, and 25, method 4000 is illustrated. For brevity, similar method steps that have been discussed above with respect to FIG. 24 may have a shortened description. Following steps 3010 to 3020, step 4030 may involve performing ion implantation to form gate electrode doping and mixed cross-coupled junctions 510, where dopant ions are introduced to create alternating N+ 242 and P+ 152 regions. In step 4040, ion implantation may be performed to form the opposite polarity in mixed cross-coupled junctions 510.

Once steps 4030 and 4040 are completed, the steps 3045-3070 may be performed as discussed in FIG. 24. Various embodiments allow for versatile configurations that may be adapted to different display requirements and manufacturing processes without an additional mask and process steps, where the process flows described herein are compatible with a process of records (POR), enabling less process variation and no larger area penalty. This flexibility ensures that the pixel driver designs can be tailored to meet specific performance and integration needs, making them suitable for a wide range of LED display applications.

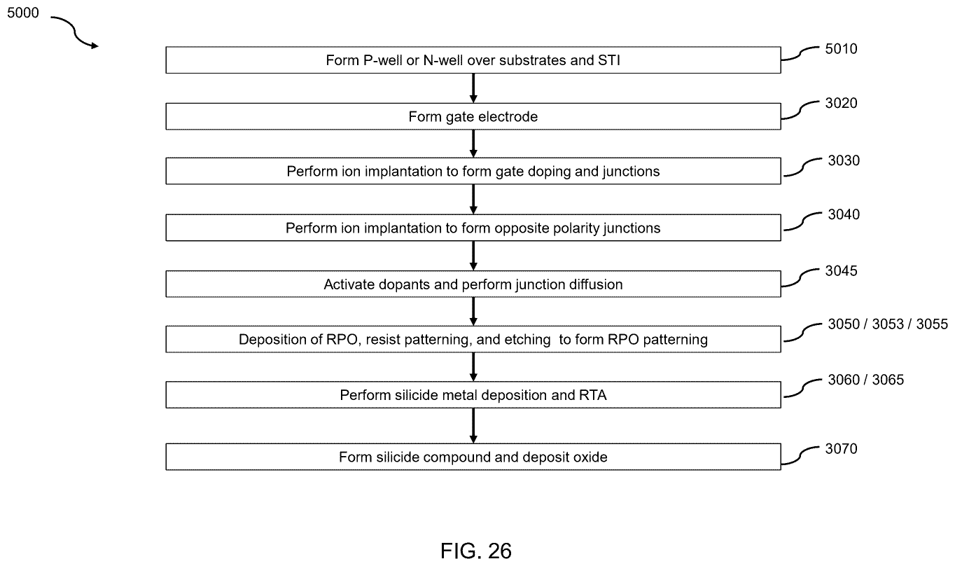

FIG. 26 is a process flowchart that illustrates the method steps to form a pixel driver transistor with diode structures and shallow trench isolation (STI). With reference to FIGS. 8A, 9A, 10A, 11A, and 26A, a method 5000 is illustrated. For brevity, similar method steps that have been discussed above with respect to FIG. 24 may have a shortened description. In step 5010, a P-well or N-well is formed over the substrate, along with the formation of STI 310 or 320.

Once step 5010 is completed, the steps 3020-3070 may be performed as discussed in FIG. 24. Various embodiments allow for versatile configurations that may be adapted to different display requirements and manufacturing processes without an additional mask and process steps, where the process flows described herein are compatible with a process of records (POR), enabling less process variation and no larger area penalty. This flexibility ensures that the pixel driver designs can be tailored to meet specific performance and integration needs, making them suitable for a wide range of LED display applications.

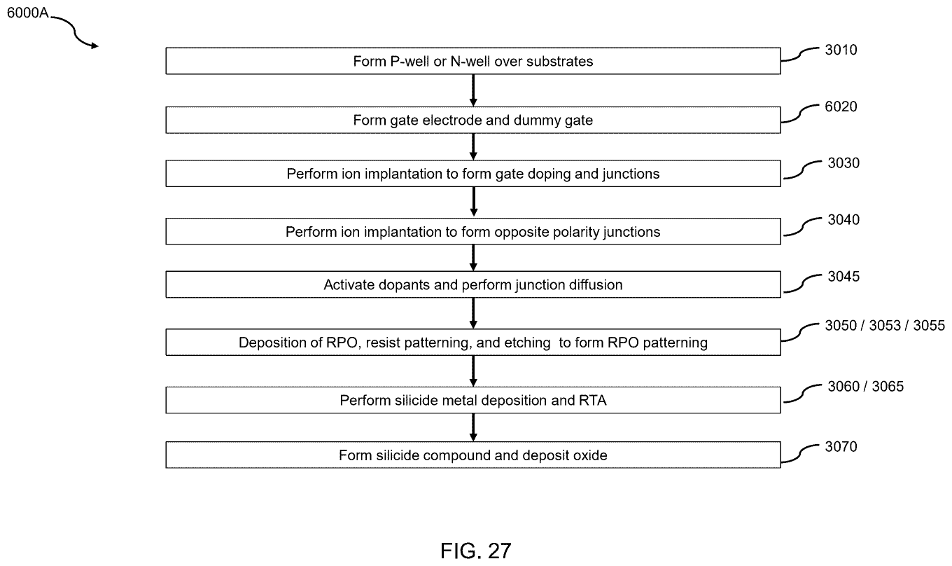

FIG. 27 is a process flowchart that illustrates the method steps to form a pixel driver transistor with diode structures using an N+ dummy gate 222 or P+ dummy gate 132. With reference to FIGS. 12A, 13A, and 27, method 6000A is illustrated. For brevity, similar method steps that have been discussed above with respect to FIG. 24 may have a shortened description. In step 3010, a P-well or N-well is formed over the substrate. In step 6020, the undoped gate electrode 100 and undoped dummy gate 102 are formed simultaneously.

Once step 6020 is completed, the steps 3030-3070 may be performed as discussed above. Various embodiments allow for versatile configurations that may be adapted to different display requirements and manufacturing processes without an additional mask and process steps, where the process flows described herein are compatible with a process of records (POR), enabling less process variation and no larger area penalty. This flexibility ensures that the pixel driver designs can be tailored to meet specific performance and integration needs, making them suitable for a wide range of LED display applications.

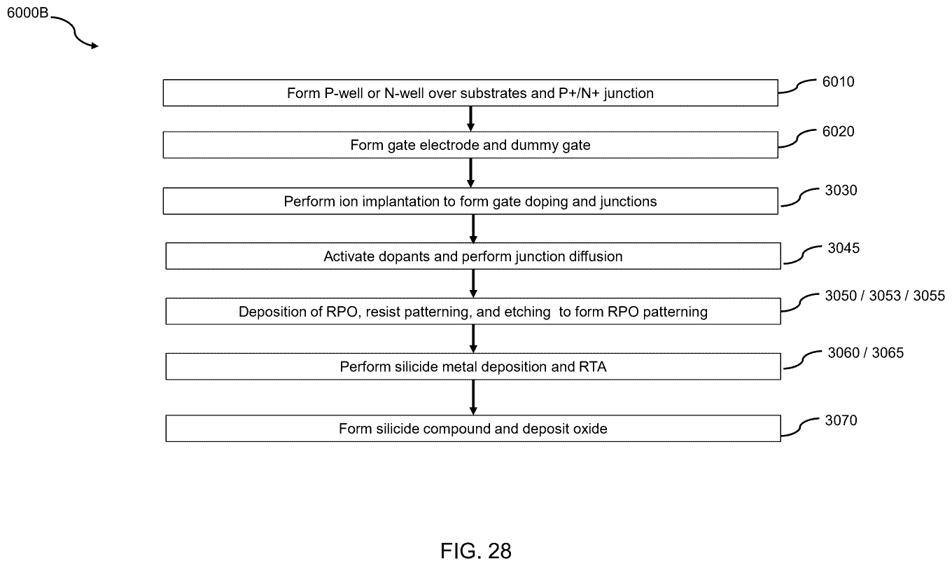

FIG. 28 is a process flowchart that illustrates the method steps to form a pixel driver transistor with diode structures using an N+ dummy gate 222 or P+ dummy gate 132. With reference to FIGS. 16A, 17A, and 28, method 6000B is illustrated. For brevity, similar method steps that have been discussed above with respect to FIG. 24 may have a shortened description. In step 6010, a P-well or N-well is formed over the substrate, and P+/N+ junctions are created. In step 6020, the undoped gate electrode 100 and undoped dummy gate 102 are formed simultaneously, where an undoped dummy gate 102 is placed over the junction between the P+ region and the N+ region.

Once the steps 6010 and 6020 are completed, the steps 3030-3070 may be performed as discussed in FIG. 24. Various embodiments allow for versatile configurations that may be adapted to different display requirements and manufacturing processes without an additional mask and process steps, where the process flows described herein are compatible with a process of records (POR), enabling less process variation and no larger area penalty. This flexibility ensures that the pixel driver designs can be tailored to meet specific performance and integration needs, making them suitable for a wide range of LED display applications.

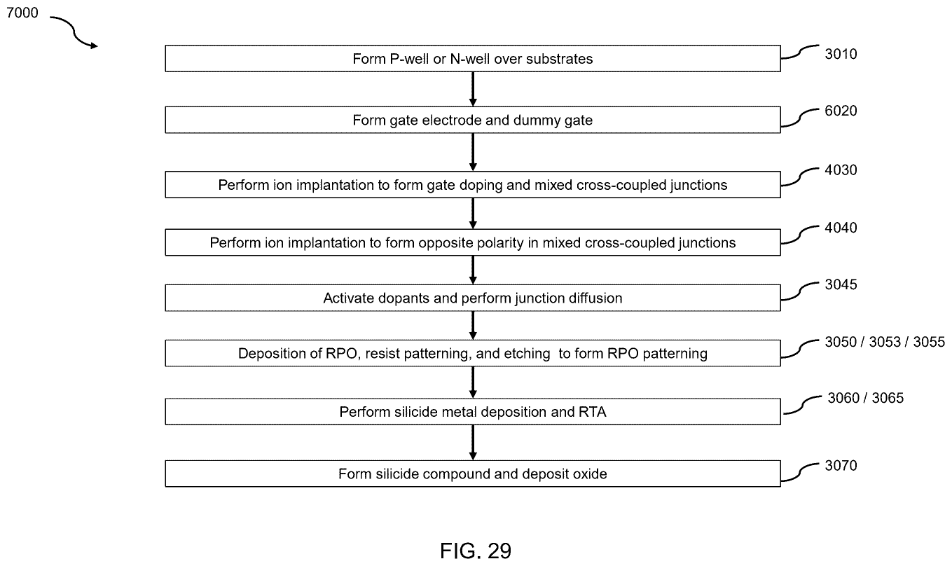

FIG. 29 is a process flowchart that illustrates the method steps to form a pixel driver transistor with mixed cross-coupled diode structures 510 and a dummy gate. With reference to FIGS. 20A, 21A, and 29, method 7000 is illustrated. For brevity, similar method steps that have been discussed above with respect to FIG. 24 may have a shortened description. Following step 3010, the undoped gate electrode 100 and undoped dummy gate 102 are formed simultaneously in step 6020. Step 4030 may involve performing ion implantation to form gate doping and mixed cross-coupled junctions 510, where dopant ions are introduced to create alternating N+ 242 and P+ 152 regions. In step 4040, ion implantation may be performed to form the opposite polarity in mixed cross-coupled junctions 510.

Once the steps 6020, 4030, and 4040 are completed, the steps 3045-3070 may be performed as discussed in FIG. 24. Various embodiments allow for versatile configurations that may be adapted to different display requirements and manufacturing processes without an additional mask and process steps, where the process flows described herein are compatible with a process of records (POR), enabling less process variation and no larger area penalty. This flexibility ensures that the pixel driver designs can be tailored to meet specific performance and integration needs, making them suitable for a wide range of LED display applications.

According to various embodiments of the present disclosure, related transistor-alone designs face challenges in achieving optimal performance for LED pixel driver circuits. These designs often struggle with providing the necessary design flexibility, voltage modulation, and high sub-threshold swing without adversely affecting transistor channel doping levels or gate oxide interface state densities, which may degrade carrier mobilities and impact current levels and reliability. Furthermore, adjusting these parameters may lead to lower current drive and potential reliability issues. Consequently, transistor-based circuits may be limited in handling the high current, threshold voltage, and sub-threshold swing required for LEDs, resulting in potential inefficiencies and reduced lifespan. Additionally, achieving the linearity and precise control needed for accurate color representation and brightness in LED displays may be challenging with transistors alone. Various embodiments disclosed herein address these issues by integrating advanced pixel driver structures that combine MOSFETs and diodes in series. This transistor-diode configuration enhances the sub-threshold swing, providing better control over the LED current and improving display uniformity and efficiency without larger area penalty, and enabling less process variation with device sub-threshold engineering. The present disclosure ensures that the process flows are compatible with a process of record (POR) without an additional mask and process knob. The improved design provides increased flexibility, allowing for more precise gray-scale control and higher power efficiency, improving performance and reliability in LED displays.

Referring to all drawings and according to various embodiments of the present disclosure, a pixel driver device may comprise a transistor T2 formed over a well, wherein the transistor T2 may include a gate electrode, a gate dielectric, and source/drain terminals; a diode structure formed over the well and coupled to the transistor T2 in a series connection, a mask structure may formed over the diode structure, wherein the mask structure is placed between metallic silicide contacts on one of the source/drain terminals and the diode, and/or shallow trench isolation (STI) structures formed around one of the source/drain terminals.

In one embodiment, the diode may include N+ region/P+ region/P-well in a NMOSFET, such that the diode and the one of the source/drain terminals are connected in series, forming transistor-diode structures 2010, 2020, 2030, 2040, 2070 and 2080. In another embodiment, the diode structure may further include P+ region/N+ region/N-well in a PMOSFET, such that the diode structure and the one of the source/drain terminals are connected in series, forming transistor-diode structures 2015, 2025, 2035, 2045, 2075, and 2085. In yet another embodiment, the diode structure may further include a mixed cross-coupled arrangement junction 510 in MOSFET, such that the diode and the one of the source/drain terminals are connected in series, wherein the mixed cross-coupled arrangement junction comprises alternating N+ and P+ regions, forming transistor-diode structures 2070, 2075, 2080, and 2085. In still another embodiment, the mask structure may include a shallow trench isolation 310 (STI) or 320 (sSTI), the STI being positioned over the well and situated between the metallic silicide 10 contacts. This may form transistor-diode structures 2010, 2015, 2020, and 2025. In a further embodiment, the mask structure may include a resist protection oxide (RPO) 410 layer, the RPO 410 being positioned over the well and situated between the metallic silicide 10 contacts. This may form transistor-diode structures 2040 and 2045. In an additional embodiment, the RPO 410 may be positioned over a junction between N+ region and P+ region of the diode, and situated between the metallic silicide 10 contacts. This may form transistor-diode structures 2060 and 2065. In a subsequent embodiment, the mask structure may include a dummy gate electrode, the dummy gate electrode being positioned over the well or over a junction between N+ region and P+ region, and situated between the metallic silicide 10 contacts. This may form diode structures 2030, 2035, 2050, 2055, 2070 and 2075. In various embodiments disclosed herein, a pixel driver device may comprise a combination of multiple diodes and mask structures such as mixed cross-coupled arrangements, RPOs, dummy gates and/or STIs formed over a well, such that various embodiments may achieve device/circuit design flexibility. In other embodiments, a pixel driver may omit or add diodes and mask structures to reflect the device/circuit design flexibility. Thus, in some embodiments, the diode structures may include a plurality of diodes.

According to another aspect of the present disclosure, a driver circuit structure comprises a scan input line, a data input line, a power supply line (PVDD), a switch transistor T1, the switch transistor including a switch transistor gate electrode, a switch transistor gate dielectric, and switch transistor source/drain terminals, wherein the scan input line is connected to the switch transistor T1 gate electrode, a driver transistor T2 including a driver transistor gate electrode, driver transistor gate dielectric, and driver transistor source/drain terminals, wherein the output of the switch transistor T1 is connected to the driver transistor T2 gate electrode, a diode connected in series with the driver transistor T2, wherein the diode is placed between one of the driver transistor source/drain terminals and the and a driver transistor gate electrode gate electrode.

In one embodiment, the diode may include N+ region/P+ region/well in a MOSFET, such that carriers from one of the source/drain terminals transport through the diode to the driver transistor gate electrode. This may form transistor-diode structures 2010, 2015, 2020, 2025, 2030, 2035, 2040, 2045, 2050, 2055, 2060, 2065, 2070, 2075, 2080, and 2085. In another embodiment, the diode may further include mixed cross-coupled arrangement junction 510 in MOSFET, wherein the mixed cross-coupled arrangement junction comprises alternating N+ and P+ regions, forming an alternating junction sequence, such that carriers from the one of source/drain terminals transport through the diode to the driver transistor gate electrode. This may form transistor-diode structures 2070, 2075, 2080, and 2085. In yet another embodiment, the driver transistor may be a PMOSFET, such that the source 156 of the PMOSFET is connected to the power supply line (PVDD), and the drain 150 of the PMOSFET is connected to the OLED pixel. In still another embodiment, the driver transistor may be a NMOSFET, such that the drain 140 of the NMOSFET is connected to the OLED pixel, and the source 246 of the NMOSFET is connected to ground or lower potential.

According to another aspect of the present disclosure, a method of forming a driver device comprises forming a transistor including source/drain terminals over a well, forming a floating diode over the well and coupled to the transistor in a series connection, forming the diode junction by ion implantation, placing a masking-structure (RPO 410 or Dummy Gate 222, 132), and STI (310, 320) to isolate a metallic contact 10 and to define a diode area, and/or forming STI configured to isolate one of the source/drain terminals In one embodiment, the method of forming the diode junction comprises forming N+ region (240, 244, 246), P+ region (150, 154, 156), and an alternating N+ 242/P+ 152 junction of a mixed cross-coupled arrangement 510 by the ion implantation. In another embodiment, the method of placing the masking-structure may comprise forming a structure placed over a junction between a N+ region and a P+ region, such that the N+ region and the P+ region have separate metallic silicide 10 contacts, forming transistor-diode structures 2050, 2055, 2060 and 2065. In yet another embodiment, the method of placing the masking-structure may further comprise forming a structure placed over the well, such that any metallic silicide 10 contact on an adjacent N+ or P+ region is isolated from the well, forming transistor-diode structure 2010, 2015, 2020, 2025, 2030, 2035, 2040, 2045, 2070, 2075, 2080 and 2085.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A pixel driver device, comprising:
a transistor formed over a well, the transistor comprising a gate electrode, a gate dielectric, source/drain terminals;
a diode structure formed over the well and coupled to the transistor in a series connection; and
a mask structure formed over the well and coupled to the transistor in a series connection;
a mask structure formed over the well, wherein the mask structure is placed between metallic silicide contacts on one of the source/drain terminals and the diode; and
a shallow trench isolation (STI) formed around one of the source/drain terminals.

2. The pixel driver device of claim 1, wherein the diode structure includes N+ region/P+ region/P-well in a NMOSFET, and P+ region/N+ region/N-well in a PMOSFET, such that the diode structure and the one of the source/drain terminals are connected in series.

3. The pixel driver device of claim 2, wherein the diode structure further includes a mixed cross-coupled arrangement junction in MOSFET, such that the diode and the one of the source/drain terminals are connected in series.

4. The pixel driver device of claim 3, wherein the mixed cross-coupled arrangement junction comprises alternating N+ and P+ regions, forming an alternating junction sequence.

5. The pixel driver device of claim 1, wherein the mask structure includes a shallow trench isolation (STI) region, the STI being positioned over the well and situated between the metallic silicide contacts.

6. The pixel driver device of claim 1, wherein the mask structure includes a resist protection oxide (RPO) layer, the RPO being positioned over the well and situated between the metallic silicide contacts.

7. The pixel driver device of claim 6, further comprising the RPO being positioned over a junction between N+ region and P+ region of the diode and situated between metallic silicide contacts.

8. The pixel driver device claim 1, wherein the mask structure includes a dummy gate, the dummy gate being positioned over the well and situated between the metallic silicide contacts.

9. The pixel driver device of claim 8, further comprising the dummy gate being positioned over a junction between N+ region and P+ region of the diode structure.

10. A driver circuit structure, comprising:
a scan input line;
a data input line;
a power supply line (PVDD);
a switch transistor comprising a switch transistor gate electrode, a switch transistor gate dielectric, switch transistor source/drain terminals, wherein the scan input line is connected to the switch transistor gate electrode;
a driver transistor comprising a driver transistor gate electrode, a driver transistor gate dielectric, driver transistor source/drain terminals, wherein one of the switch transistor source/drain terminals is connected to the driver transistor gate electrode; and
a diode connected in series with the driver transistor, wherein the diode is placed between one of the driver transistor source/drain terminals and the driver transistor gate electrode.

11. The driver circuit structure of claim 10, wherein the diode includes N+ region/P+ region/well in a MOSFET, such that carriers from the driver transistor source/drain terminal transport through the diode to the driver transistor gate electrode.

12. The driver circuit structure of claim 11, wherein the diode further includes a mixed cross-coupled arrangement junction in MOSFET, such that carriers from the driver transistor source/drain terminal transport through the diode to the driver transistor gate electrode.

13. The driver circuit structure of claim 12, wherein the mixed cross-coupled arrangement junction comprises alternating N+ and P+ regions, forming an alternating junction sequence.

14. The driver circuit structure of claim 10, wherein pixel driver transistor is a PMOSFET, such that one of the driver transistor source/drain terminals is connected to the power supply line (PVDD), and an other driver transistor source/drain terminal is connected to the LED pixel.

15. The driver circuit structure of claim 10, wherein the driver transistor is a NMOSFET, such that one of the driver transistor source/drain terminals is connected to the LED pixel, and an other driver transistor source/drain terminal is connected to ground or lower potential.

16. A method of forming a driver device comprising:
forming a well by patterning the well, implanting dopants in the well, and annealing the well;
fabricating a transistor including patterning a gate electrode, and forming source/drain terminals over the well;
forming the diode junction by patterning the diode junction, implanting dopants in the diode junction, and annealing the diode junction;
configuring the diode junction electrically floated and coupled to the transistor in a series connection;
placing a masking-structure to isolate a metallic contact; and
forming STI configured to isolate one of source/drain terminals over the well.

17. The method of claim 16, wherein the forming the diode junction comprises forming N+ region, P+ region, and an alternating N+/P+ junction of a mixed cross-coupled arrangement by the ion implantation.

18. The method of claim 16, wherein the placing the masking-structure comprises forming a resist protection oxide (RPO) and a dummy gate placed over a junction between a N+ region and a P+ region, such that the N+ region and the P+ region have separate metallic contacts.

19. The method of claim 18, wherein the placing the masking-structure further comprises forming a resist protection oxide (RPO) and a dummy gate placed over a well, such that any metallic contact on an adjacent N+ or P+ region is isolated from the well.

20. The method of claim 16, wherein the forming STI further comprises fabricating a shadow STI (SSTI) configured to obtain a reduced depth of STI.
